(19) United States
(12) Patent Application Publication
(10) Pub. No.: US 2025/0174550 A1
(43) Pub. Date: May 29, 2025

(54) THREE-DIMENSIONAL MEMORY DEVICE WITH VARIABLE WORD LINE VIA CONTACT DENSITY AS FUNCTION OF CONTACT DEPTH AND METHODS OF FORMING THE SAME

(71) Applicant: WESTERN DIGITAL TECHNOLOGIES, INC.,, SAN JOSE, CA (US)

(72) Inventors: Takayuki MAEKURA, Yokkaichi (JP); Tomohiro KUBO, Yokkaichi (JP); Masanori TERAHARA, Yokkaichi (JP); Satoshi YOSHIKAWA, Yokkaichi (JP); Hideaki HASEGAWA, Yokkaichi (JP)

(21) Appl. No.: 18/523,129

(22) Filed: Nov. 29, 2023

(51) Int. Cl. H01L 23/522; G11C 16/04; H01L 23/528; H10B 41/10; H10B 41/27; H10B 41/35; H10B 43/10; H10B 43/27; H10B 43/35

(52) U.S. Cl. CPC H01L 23/5226; G11C 16/0483; H01L 23/5283; H10B 41/10; H10B 41/27; H10B 41/35; H10B 43/10; H10B 43/27; H10B 43/35

(57) ABSTRACT

A three-dimensional memory device includes an alternating stack of insulating layers and electrically conductive layers, memory openings vertically extending through the alternating stack, memory opening fill structures located in the memory openings, and an array of layer contact via structures. Each of the layer contact via structures contacts a respective one of the electrically conductive layers. A shallower first subset of the layer contact via structures has a higher density per unit area than a deeper second subset of the layer contact via structures.

### FIELD

The present disclosure relates generally to the field of semiconductor devices, and particularly to a three-dimensional memory device with variable word line via contact density as function of contact depth and methods of forming the same.

### BACKGROUND

A three-dimensional memory device including a three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device comprises an alternating stack of insulating layers and electrically conductive layers; memory openings vertically extending through the alternating stack; memory opening fill structures located in the memory openings, wherein each of the memory opening fill structures comprises a respective vertical semiconductor channel and a vertical stack of memory elements; and an array of layer contact via structures. Each of the layer contact via structures contacts a respective one of the electrically conductive layers and vertically extends through a respective subset of layers within the alternating stack that overlies the respective one of the electrically conductive layers; and a shallower first subset of the layer contact via structures has a higher density per unit area than a deeper second subset of the layer contact via structures.

According to another aspect of the present disclosure, a method of forming a three-dimensional memory device comprises forming an alternating stack of insulating layers and spacer material layers, wherein the spacer material layers are formed are or are subsequently replaced with electrically conductive layers; forming memory openings through the alternating stack; forming memory opening fill structures in the memory openings, wherein each of the memory opening fill structures comprises a respective vertical semiconductor channel and a vertical stack of memory elements; and forming an array of layer contact via structures. Each of the layer contact via structures is formed on a respective one of the electrically conductive layers and vertically extends through a respective subset of layers within the alternating stack that overlies the respective one of the electrically conductive layers; and a shallower first subset of the layer contact via structures has a higher density per unit area than a deeper second subset of the layer contact via structures.

### BRIEF DESCRIPTION OF THE DRAWINGS

FIG. 1 is a schematic vertical cross-sectional view of an exemplary structure after formation of an alternating stack of insulating layers and sacrificial material layers over a substrate according to a first embodiment of the present disclosure.

FIG. 2A is a top-down view of a region of the exemplary structure after formation of memory openings and support openings according to an embodiment of the present disclosure.

FIG. 2B is a vertical cross-sectional view of the exemplary structure along the vertical plane B-B′ of FIG. 2A.

FIG. 3A is a top-down view of a region of the exemplary structure after formation of sacrificial opening fill structures according to an embodiment of the present disclosure.

FIG. 3B is a vertical cross-sectional view of the exemplary structure along the vertical plane B-B′ of FIG. 3A.

FIG. 4A is a top-down view of a region of the exemplary structure after replacement of sacrificial support opening fill structures with support pillar structures according to an embodiment of the present disclosure.

FIG. 4B is a vertical cross-sectional view of the exemplary structure along the vertical plane B-B′ of FIG. 4A.

FIG. 5A is a top-down view of a region of the exemplary structure after removal of sacrificial memory opening fill structures according to an embodiment of the present disclosure.

FIG. 5B is a vertical cross-sectional view of the exemplary structure along the vertical plane B-B′ of FIG. 5A.

FIG. 6A is a top-down view of a region of the exemplary structure after formation of memory opening fill structures according to an embodiment of the present disclosure.

FIG. 6B is a vertical cross-sectional view of the exemplary structure along the vertical plane B-B′ of FIG. 6A.

FIG. 6C is a vertical cross-sectional view of a region around a memory opening fill structure in the exemplary structure of FIGS. 6A and 6B.

FIG. 7A is a top-down view of a region of the exemplary structure after formation of an insulating cap layer and a patterned hard mask layer according to an embodiment of the present disclosure.

FIG. 7B is a vertical cross-sectional view of the exemplary structure along the vertical plane B-B′ of FIG. 7A.

FIGS. 8A-8F are sequential schematic vertical cross-sectional view of region of the exemplary structure during formation of layer contact via cavities according to an embodiment of the present disclosure.

FIG. 9A is a top-down view of a region of the exemplary structure after formation of contact via openings and removal of the patterned hard mask layer according to an embodiment of the present disclosure.

FIG. 9B is a vertical cross-sectional view of the exemplary structure along the vertical plane B-B′ of FIG. 9A.

FIG. 9C is a vertical cross-sectional view of the exemplary structure along the vertical plane C-C′ of FIG. 9A.

FIGS. 10A-10C are top-down views of alternative configuration of the exemplary structure after the processing steps of FIGS. 9A-9C according to an embodiment of the present disclosure.

FIG. 11A is a top-down view of a region of the exemplary structure after formation of sacrificial via fill structures and removal of the patterned hard mask layer according to an embodiment of the present disclosure.

FIG. 11B is a vertical cross-sectional view of the exemplary structure along the vertical plane B-B′ of FIG. 11A.

FIG. 11C is a vertical cross-sectional view of the exemplary structure along the vertical plane C-C′ of FIG. 11A.

FIG. 12A is a top-down view of a region of the exemplary structure after formation of a contact-level dielectric layer, lateral isolation trenches, and source regions according to an embodiment of the present disclosure.

FIG. 12B is a vertical cross-sectional view of the exemplary structure along the vertical plane B-B′ of FIG. 12A.

FIG. 12C is a vertical cross-sectional view of the exemplary structure along the vertical plane C-C′ of FIG. 12A.

FIG. 13A is a top-down view of a region of the exemplary structure after formation of lateral recesses according to an embodiment of the present disclosure.

FIG. 13B is a vertical cross-sectional view of the exemplary structure along the vertical plane B-B′ of FIG. 13A.

FIG. 13C is a vertical cross-sectional view of the exemplary structure along the vertical plane C-C′ of FIG. 13A.

FIG. 14A is a top-down view of a region of the exemplary structure after formation of electrically conductive layers according to an embodiment of the present disclosure.

FIG. 14B is a vertical cross-sectional view of the exemplary structure along the vertical plane B-B′ of FIG. 14A.

FIG. 14C is a vertical cross-sectional view of the exemplary structure along the vertical plane C-C′ of FIG. 14A.

FIG. 15A is a top-down view of a region of the exemplary structure after formation of lateral isolation trench fill structures according to an embodiment of the present disclosure.

FIG. 15B is a vertical cross-sectional view of the exemplary structure along the vertical plane B-B′ of FIG. 15A.

FIG. 15C is a vertical cross-sectional view of the exemplary structure along the vertical plane C-C′ of FIG. 15A.

FIG. 16A is a top-down view of a region of the exemplary structure after formation of connection via openings according to an embodiment of the present disclosure.

FIG. 16B is a vertical cross-sectional view of the exemplary structure along the vertical plane B-B′ of FIG. 16A.

FIG. 16C is a vertical cross-sectional view of the exemplary structure along the vertical plane C-C′ of FIG. 16A.

FIG. 17A is a top-down view of a region of the exemplary structure after formation of layer contact via cavities according to an embodiment of the present disclosure.

FIG. 17B is a vertical cross-sectional view of the exemplary structure along the vertical plane B-B′ of FIG. 17A.

FIG. 17C is a vertical cross-sectional view of the exemplary structure along the vertical plane C-C′ of FIG. 17A.

FIG. 18A is a top-down view of a region of the exemplary structure after formation of layer contact via structures according to an embodiment of the present disclosure.

FIG. 18B is a vertical cross-sectional view of the exemplary structure along the vertical plane B-B′ of FIG. 18A.

FIG. 18C is a vertical cross-sectional view of the exemplary structure along the vertical plane C-C′ of FIG. 18A.

FIGS. 19A-19C are top-down views of alternative configuration of the exemplary structure after the processing steps of FIGS. 18A-18C according to an embodiment of the present disclosure.

### DETAILED DESCRIPTION

As discussed above, the embodiments of the present disclosure are directed to a three-dimensional memory device with variable word line via contact density as function of contact depth and methods of forming the same, the various aspects of which are described below. The embodiments of the present disclosure can be used to form various structures including a multilevel memory structure, non-limiting examples of which include three-dimensional memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are used merely to identify similar elements, and different ordinals may be used across the specification and the claims of the instant disclosure. The same reference numerals refer to the same element or similar element. Unless otherwise indicated, elements having the same reference numerals are presumed to have the same composition. Unless otherwise indicated, a “contact” between elements refers to a direct contact between elements that provides an edge or a surface shared by the elements. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “prototype” structure or an “in-process” structure refers to a transient structure that is subsequently modified in the shape or composition of at least one component therein. As used herein, a first electrical component is electrically connected to a second electrical component if there exists an electrically conductive path between the first electrical component and the second electrical component.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that can be attached to a circuit board through a set of pins or solder balls. A semiconductor package may include a semiconductor chip (or a “chip”) or a plurality of semiconductor chips that are bonded thereamongst, for example, by flip-chip bonding or another chip-to-chip bonding. A package or a chip may include a single semiconductor die (or a “die”) or a plurality of semiconductor dies. A die is the smallest unit that can independently execute external commands or report status. Typically, a package or a chip with multiple dies is capable of simultaneously executing as many external commands as the total number of dies therein. Each die includes one or more planes. Identical concurrent operations can be executed in each plane within a same die, although there may be some restrictions. In case a die is a memory die, i.e., a die including memory elements, concurrent read operations, concurrent write operations, or concurrent erase operations can be performed in each plane within a same memory die. Each plane contains a number of memory blocks (or “blocks”), which are the smallest unit that can be erased by in a single erase operation. Each memory block contains a number of pages, which are the smallest units that can be selected for programming.

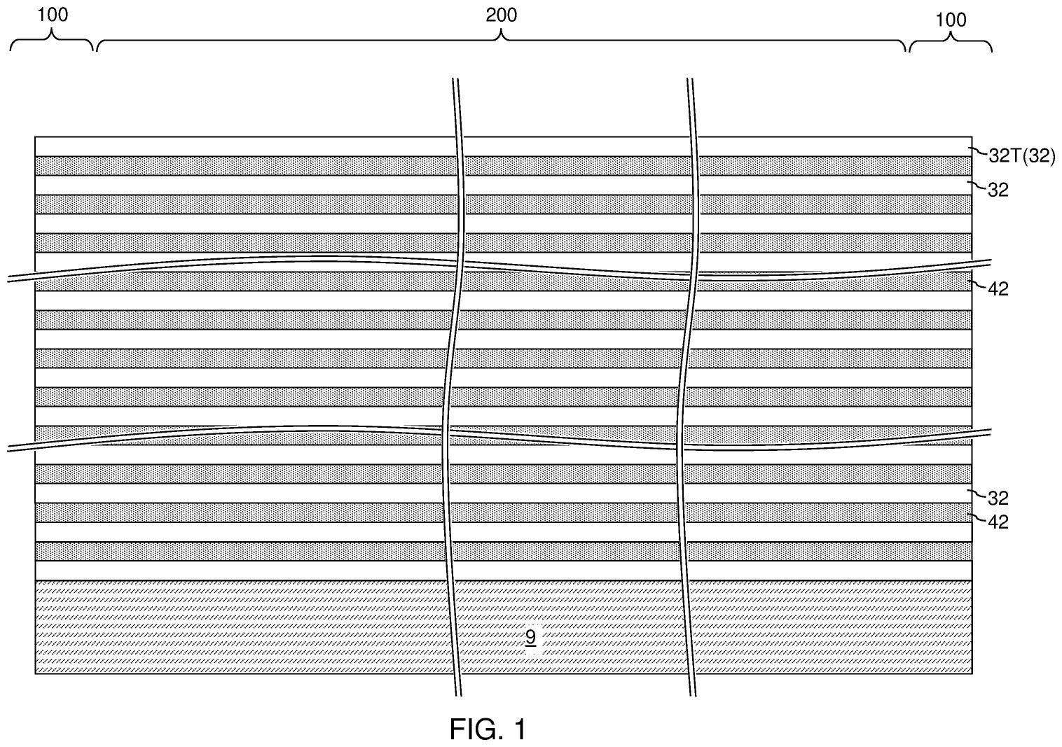

Referring to FIG. 1, an exemplary structure according to an embodiment of the present disclosure is illustrated, which can be used, for example, to fabricate a device structure containing vertical NAND memory devices. The exemplary structure includes a substrate including a semiconductor material layer at least at an upper portion thereof. The semiconductor material layer 9 includes at least one elemental semiconductor material (e.g., a doped well in a single crystal silicon wafer or a deposited silicon layer), at least one III-V compound semiconductor material, at least one II-VI compound semiconductor material, at least one organic semiconductor material, or other semiconductor materials known in the art. In one embodiment, the semiconductor material layer may comprise a semiconductor material having a doping of a first conductivity type.

An alternating stack (32, 46) of insulating layers 32 and spacer material layers can be formed over a semiconductor material layer 9. The spacer material layers are formed as, or are subsequently replaced with, electrically conductive layers. In case the spacer material layers are subsequently replaced with the electrically conductive layers, the spacer material layers may be formed as sacrificial material layers 42. In this case, a stack of an alternating plurality of insulating layers 32 and sacrificial material layers 42 can be formed over the semiconductor material layer 9. The stack of the alternating plurality is herein referred to as an alternating stack (32, 42).

In one embodiment, the alternating stack (32, 42) can include insulating layers 32 composed of the first material, and sacrificial material layers 42 composed of a second material different from that of insulating layers 32. The first material of the insulating layers 32 can be at least one insulating material. As such, each insulating layer 32 can be an insulating material layer. Insulating materials that can be used for the insulating layers 32 include, but are not limited to, silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 can be silicon oxide.

The second material of the sacrificial material layers 42 is a sacrificial material that can be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The sacrificial material layers 42 may comprise a dielectric material. In one embodiment, the sacrificial material layers 42 may comprise, and/or may consist essentially of, silicon nitride. The insulating layers 32 can be deposited, for example, by chemical vapor deposition (CVD). For example, if silicon oxide is used for the insulating layers 32, tetraethyl orthosilicate (TEOS) can be used as the precursor material for the CVD process. The sacrificial material layers 42 can be formed, for example, CVD or atomic layer deposition (ALD).

The thicknesses of the insulating layers 32 and the sacrificial material layers 42 can be in a range from 20 nm to 50 nm, although lesser and greater thicknesses can be used for each insulating layer 32 and for each sacrificial material layer 42. The number of repetitions of the pairs of an insulating layer 32 and a sacrificial material layer (e.g., a control gate electrode or a sacrificial material layer) 42 can be in a range from 2 to 1,024, and typically from 8 to 256, although a greater number of repetitions can also be used. The top and bottom gate electrodes in the stack may function as the select gate electrodes. In one embodiment, each sacrificial material layer 42 in the alternating stack (32, 42) can have a uniform thickness that is substantially invariant within each respective sacrificial material layer 42. The topmost one of the insulating layers 32 is herein referred to as a topmost insulating layer 32T.

The sacrificial material layers are replaced with electrically conductive layers in subsequent processing steps. The contact via structures that are subsequently formed to provide electrical contact to the electrically conductive layers are herein referred to as layer contact via structures, which may comprise word line contact via structures and/or select gate contact via structures, such as drain and/or source side select gate contact via structures. The exemplary structure comprises a contact region 200 in which the layer contact via structures are to be subsequently formed, and at least one memory array region 100. The memory array region or regions 100 are laterally spaced from the contact region 200 and are employed to form three-dimensional memory arrays.

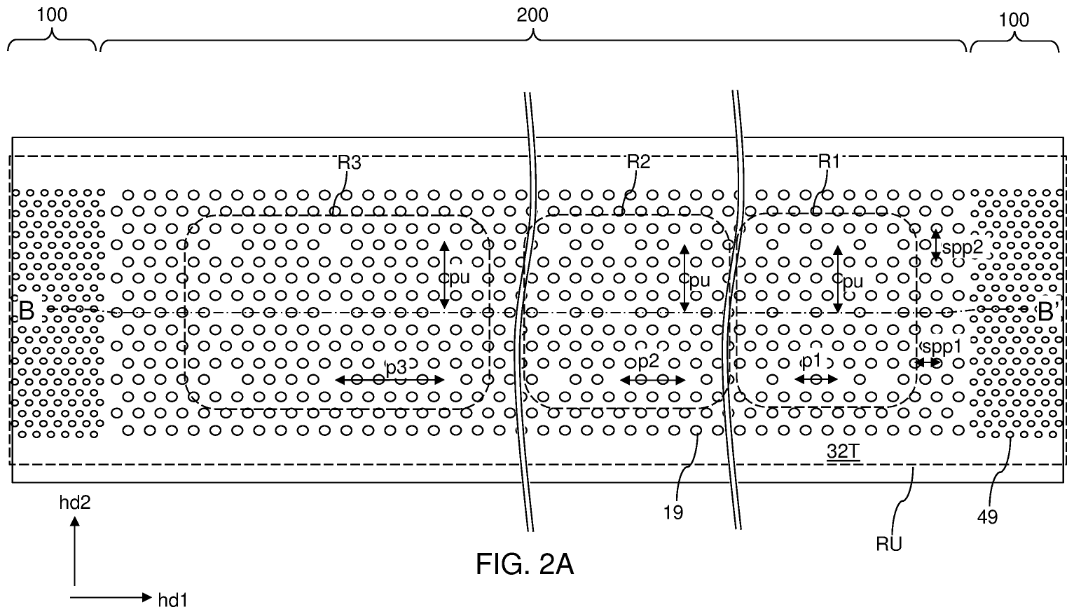

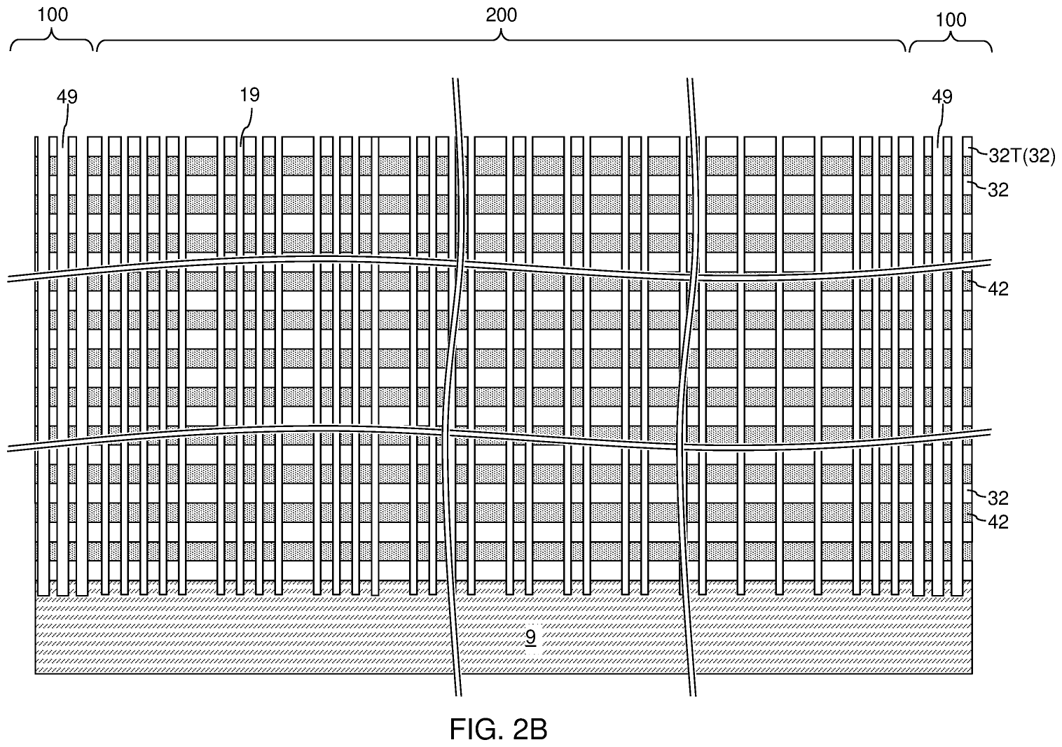

Referring to FIGS. 2A-2C, a lithographic material stack (not shown) including at least a photoresist layer can be formed over the alternating stack (32, 42), and can be lithographically patterned to form openings therein. The pattern in the lithographic material stack can be transferred through the alternating stack (32, 42) and through the alternating stack (32, 42) by at least one anisotropic etch that uses the patterned lithographic material stack as an etch mask. Portions of the alternating stack (32, 42) and underlying the openings in the patterned lithographic material stack are etched to form memory openings 49 in the memory array regions 100 and to form support openings 19 in the contact region 200. As used herein, a “memory opening” refers to an opening in which memory elements, such as a memory stack structure, is subsequently formed. As used herein, a “support opening” refers to an opening in which an electrically inactive structure that provides structural support is subsequently formed.

The memory openings 49 and the support openings extend through the entirety of the alternating stack (32, 42). The chemistry of the anisotropic etch process used to etch through the materials of the alternating stack (32, 42) can alternate to optimize etching of the first and second materials in the alternating stack (32, 42). The anisotropic etch can be, for example, a series of reactive ion etches. The sidewalls of the memory openings 49 and the support openings 19 can be substantially vertical, or can be tapered. The patterned lithographic material stack can be subsequently removed, for example, by ashing.

The memory openings 49 and the support openings 19 can extend from the top surface of the alternating stack (32, 42) to at least the horizontal plane including the topmost surface of the semiconductor material layer 9. In one embodiment, an overetch into the semiconductor material layer 9 may be optionally performed after the top surface of the semiconductor material layer 9 is physically exposed at a bottom of each memory opening 49 and at a bottom of each support opening 19. The overetch may be performed prior to, or after, removal of the lithographic material stack. In other words, the recessed surfaces of the semiconductor material layer 9 may be vertically offset from the un-recessed top surfaces of the semiconductor material layer 9 by a recess depth. The recess depth can be, for example, in a range from 1 nm to 50 nm, although lesser and greater recess depths can also be used. The overetch is optional, and may be omitted. The lithographic mask stack can be subsequently removed, for example, by ashing.

In one embodiment, the memory openings 49 may have a horizontal cross-sectional shape of a circle. In one embodiment, the support openings 19 may have a horizontal cross-sectional shape of a circle having the same or different diameter than the diameter of the memory openings 19.

In one embodiment, the memory openings 49 may be arranged in rows that laterally extend along a first horizontal direction hd1 (e.g., word line direction). The rows of memory openings 49 may be laterally spaced from each other along a second horizontal direction hd2 (e.g., bit line direction) that is perpendicular to the first horizontal direction hd1. In one embodiment, the pattern of the memory openings 49 and the support openings 19 may be formed as a periodic pattern that is repeated along the second horizontal direction hd2. In this case, a repetition unit (e.g., a memory block) RU may have a rectangular areas having a pair of lengthwise sidewalls that laterally extends along the first horizontal direction hd1. The repetition unit RU may be repeated along the second horizontal direction hd2 with a periodicity that equals the width of the rectangular area along the second horizontal direction hd2. Each repletion unit RU may have at least one two-dimensional array of memory openings 49 formed within a respective memory array region 100, and a respective two-dimensional array of support openings 19 formed within a contact region 200. In one embodiment, each repetition unit RU may comprise two two-dimensional arrays of memory openings 49 that are laterally spaced from each other along the first horizontal direction hd1 by the contact region 200.

In one embodiment, each two-dimensional array of memory openings 49 may comprise a periodic two-dimensional array of memory openings 49, such as a two-dimensional hexagonal array of memory openings 49. As used herein, a hexagonal array refers to any array in which the lattice sites are formed by a hexagon having three pairs of parallel edges. The hexagon may optionally be a regular hexagon (i.e., a hexagon having six edges of equal length).

In one embodiment, each two-dimensional array of support openings 49 may comprise a periodic two-dimensional array of support openings 19, such as a two-dimensional hexagonal array of support openings 19. In this embodiment, variable density layer contact via structures to be formed during a subsequent step extend through the areas of some of the support openings 19 (i.e., through support pillar structures that will be formed in the respective memory openings 19).

In an alternative embodiment, the variable density layer contact via structures do not extend through areas of the support openings (i.e., do not extend through support pillar structures). In this alternative embodiment shown in FIG. 2A, the support openings 19 may be formed as a quasi-periodic two-dimensional array of support openings 19. As used herein, a “quasi-periodic” two-dimensional array of elements refers to a two-dimensional array of elements in which each element is located at a respective lattice site of a periodic two-dimensional array while a subset of lattice sites within the periodic two-dimensional array are “vacancy” lattice sites that do not contain any of the elements (i.e., do not contain a support opening 19). In other words, a two-dimensional quasi-periodic array of elements is derived from a two-dimensional periodic array of elements by omitting a subset of the elements from some of the “vacancy” lattice sites of the two-dimensional periodic array of elements. As used herein, a “lattice site” within a two-dimensional periodic array of elements refers to the primary lattice sites corresponding to locations at which the elements of the two-dimensional periodic array located or the vacancy sites.

The support openings 19 within the quasi-periodic two-dimensional array of support openings 19 can be located at the primary subset of lattice sites of a first periodic two-dimensional array having a first support-pillar periodicity spp1 along a first horizontal direction hd1 and having a second support-pillar periodicity spp2 along a second horizontal direction hd2 in a plan view. A plan view refers to a view along a vertical direction perpendicular to the top surface of the substrate 9, such as a see-through top-down view or a see-through bottom-up view. The support openings 19 are absent in a complementary (i.e., “vacancy”) subset of the lattice sites of the first periodic two-dimensional array, which is the complementary subset of the primary subset. In other words, the complementary subset does not have any intersection with the primary subset, and the union of the complementary subset and the primary subset forms a two-dimensional periodic array.

The complementary subset of the lattice sites defines locations (i.e., the “vacancy” sites) at which support openings 19 are not present relative to a hypothetical two-dimensional periodic array of support openings that includes each support opening 19 in the quasi-periodic two-dimensional array of support openings 19. Therefore, the lattice sites of the complementary subset are herein referred to as vacancy sites, i.e., sites at which the support openings 19 are omitted. According to an aspect of the present disclosure, the vacancy sites may be arranged as a plurality of periodic arrays having different periodicities. Each periodic array of vacancy sites may be located in a respective region, which may comprise, for example, a first region R1 including a first periodic array of vacancy sites, a second region R2 including a second periodic array of vacancy sites, and a third region R3 including a third periodic array of vacancy sites.

In one embodiment, the a first periodic array of vacancy sites may have a first periodic pitch p1 along a first periodicity direction (e.g., the first horizontal direction hd1) and a uniform pitch pu along a second periodicity direction (e.g., the second horizontal direction hd2) that is perpendicular to the first periodicity direction. The second periodic array of vacancy sites may have a second periodic pitch p2 along the first periodicity direction and the uniform pitch pu along the second periodicity direction. The third periodic array of vacancy sites may have a third periodic pitch p3 along the third periodicity direction and the uniform pitch pu along the second periodicity direction. The first periodicity direction may be parallel to the first horizontal direction hd1 or may be parallel to the second horizontal direction hd2. In the illustrative example of FIG. 2A, the first periodicity direction is parallel to the first horizontal direction hd1, and is perpendicular to the second horizontal direction hd2.

In one embodiment, each of the first periodic pitch p1, the second periodic pitch p2, and the third periodic pitch p3 may be commensurate of the first pitch of the support openings 19 along the first periodicity direction in the quasi-periodic two-dimensional array of support openings 19. In one embodiment, the first periodic pitch p1, the second periodic pitch p2, and the third periodic pitch p3 may be different from each other. In one embodiment, the first periodic pitch p1 may be less than the second periodic pitch p2, and the second periodic pitch p2 may be less than the third periodic pitch p3. In the illustrative example of FIGS. 2A and 2B, the ratio of the first periodic pitch p1 to the first pitch spp1 of the support openings 19 along the first periodicity direction is 2; the ratio of the second periodic pitch p2 to the first pitch spp1 is 3, and the ratio of the third periodic pitch p3 to the first pitch spp1 is 5. While the periodic pitches are illustrated as integral multiples of the first pitch spp1, non-integral ratios may be used.

In one embodiment, the first uniform pitch pu may be commensurate of the second pitch of the support openings 19 along the second periodicity direction. In the illustrative example of FIGS. 2A and 2B, the ratio of the uniform pitch pu to the second pitch spp2 of the support openings 19 along the second periodicity direction within the hypothetical two-dimensional periodic array of support openings is 2. However, other integral or non-integral ratios may be used.

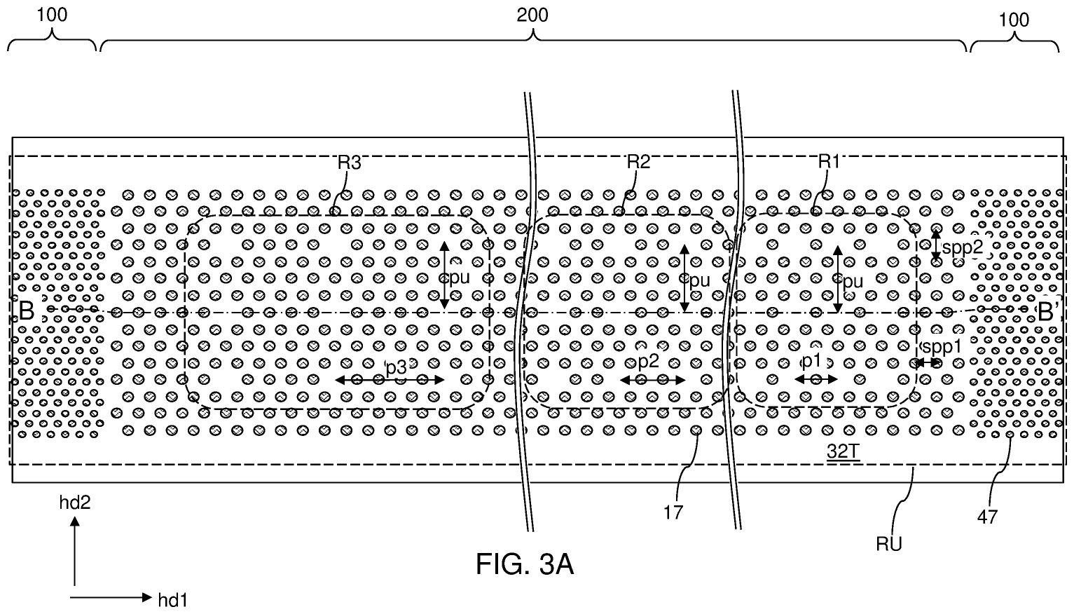

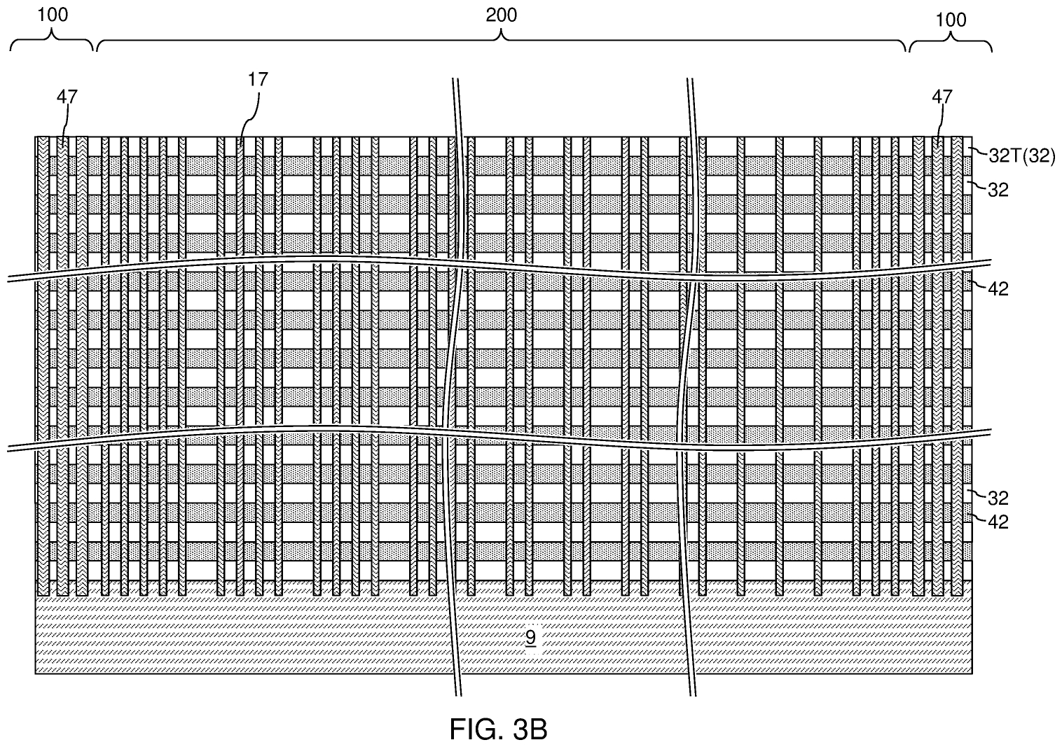

Referring to FIGS. 3A and 3B, a sacrificial fill material such as amorphous carbon, diamond-like carbon, a polymer material, or organosilicate glass can be deposited in the memory openings 49 and the support openings 19. Excess portions of the sacrificial fill material can be removed from above the horizontal plane including the topmost insulating layer 32T by performing a planarization process, which may comprise a chemical mechanical polishing (CMP) process and/or a recess etch process. Each remaining portion of the sacrificial fill material filling a memory opening 49 constitutes a sacrificial memory opening fill structure 47. Each remaining portion of the sacrificial fill material filling a support opening 19 constitutes a sacrificial support opening fill structure.

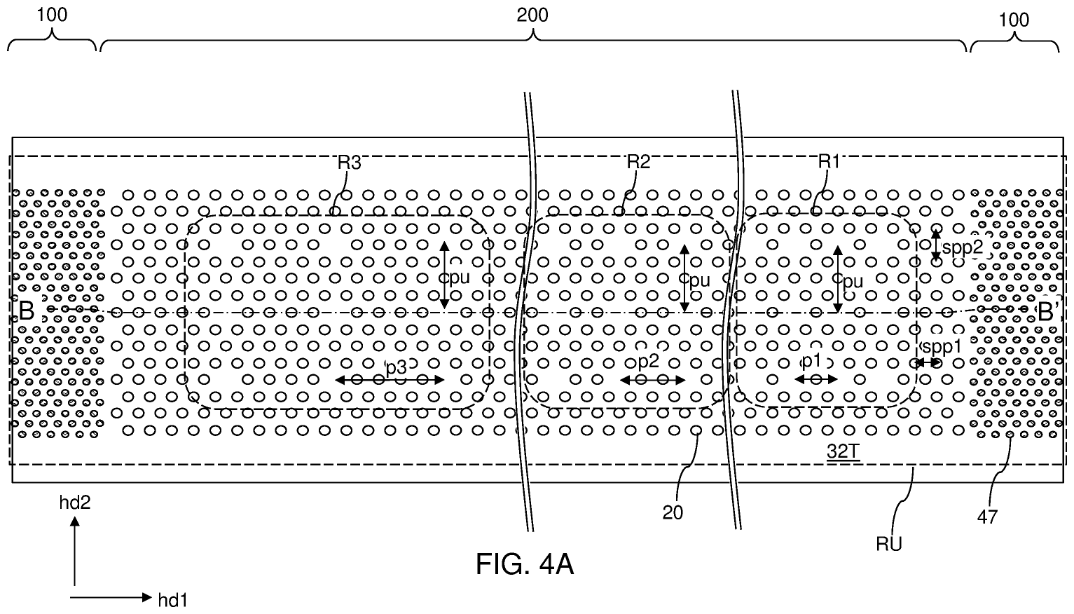

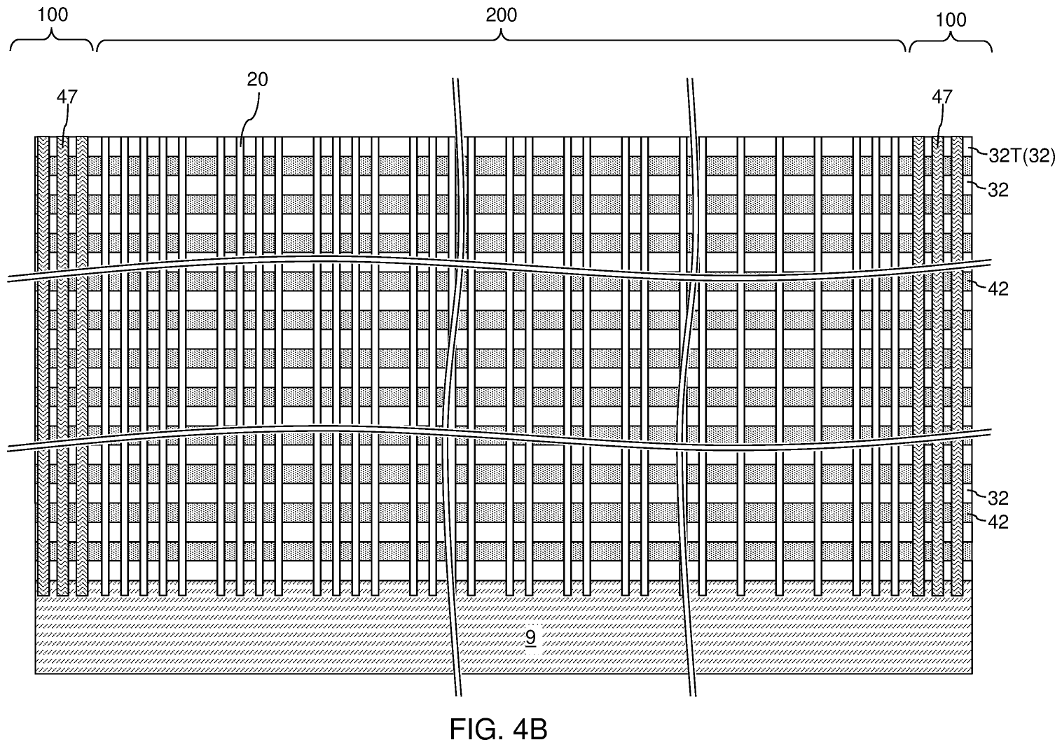

Referring to FIGS. 4A and 4B, a sacrificial cover liner (not shown) can be deposited over the alternating stack (32, 42). The sacrificial cover layer may comprise a dielectric material. A photoresist layer (not shown) can be applied over the sacrificial cover liner, and can be lithographically patterned to cover the memory array regions 100 without covering the contact region 200. A selective removal process can be performed to remove the sacrificial support opening fill structures selective to the materials of the alternating stack (32, 42) and the semiconductor material layer 9. The selective removal process may comprise an ashing process or a selective wet etch process. Voids are formed in the volumes of support openings 19. The photoresist layer may be removed during removal of the sacrificial support opening fill structures or after removal of the sacrificial support opening fill structures.

A dielectric fill material, such as silicon oxide, can be deposited in the voids of the support openings 19. Excess portions of the dielectric fill material can be removed from above the horizontal plane including the top surface of the topmost insulating layers 32T by performing a planarization process, which may comprise a chemical mechanical polishing process and/or a recess etch process. The sacrificial cover liner may be collaterally removed during the planarization process. Each remaining portion of the dielectric fill material that fills a respective one of the support openings 19 constitutes a support pillar structure 20.

A quasi-periodic two-dimensional array of support pillar structures 20 vertically extends through the alternating stack (32, 46) in the contact region 200. The support pillar structures 20 in the quasi-periodic two-dimensional array are located at a primary subset of lattice sites of a first periodic two-dimensional array having a first support-pillar periodicity along a first horizontal direction hd1 and having a second support-pillar periodicity along a second horizontal direction hd2 in a plan view. The first support pillar periodicity may be the same as a center-to-center distance between a neighboring pair of support pillar structures 20 along the first horizonal direction hd1. The second support pillar periodicity may be the same as a center-to-center distance between a neighboring pair of support pillar structures 20 along the second horizontal direction hd2. A subset of the vacancy lattice sites of the first periodic two-dimensional array at which the support pillar structures 20 are not present can be located at a complementary subset of the lattice sites of the first periodic two-dimensional array, which can be the complementary subset of the primary subset. In other words, the union of the primary subset and the complementary subset constitutes the first periodic two-dimensional array.

The complementary subset of the vacncy lattice sites of the first periodic two-dimensional array may comprise a first subset of the complementary subset located in the first region R1, a second subset of the complementary subset located in the second region R2, and a third subset of the complementary subset located in the third region R3. The lattice sites of the first subset of the complementary subset may have the first periodic pitch p1 along a first periodicity direction (which may be the first horizontal direction hd1) and may have the uniform pitch pu along a second periodicity direction (which may be the second horizontal direction hd2). The lattice sites of the second subset of the complementary subset may have the second periodic pitch p2 along the first periodicity direction and may have the uniform pitch pu along the second periodicity direction. The lattice sites of the third subset of the complementary subset may have the third periodic pitch p3 along the first periodicity direction and may have the uniform pitch pu along the second periodicity direction. In one embodiment, each of the first periodic pitch p1, the second periodic pitch p2, and the third periodic pitch p3 may be multiples (e.g., integer multiples) of the first support-pillar periodicity spp1 along the first horizontal direction hd1, and the uniform pitch pu may be a multiple (e.g., integer multiple) of the second support-pillar periodicity spp2 along the second horizontal direction hd2. The value of the integer multiples may be, for example, one or more, such as 1, 2, 3, 4, 5, 6, 7, 8, 9, 10, etc.

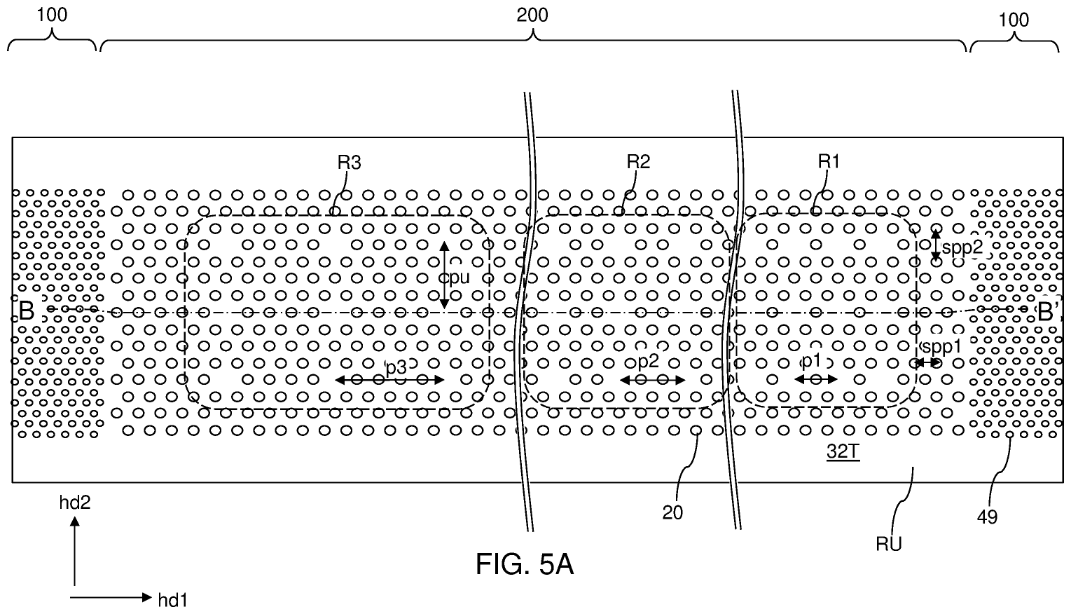

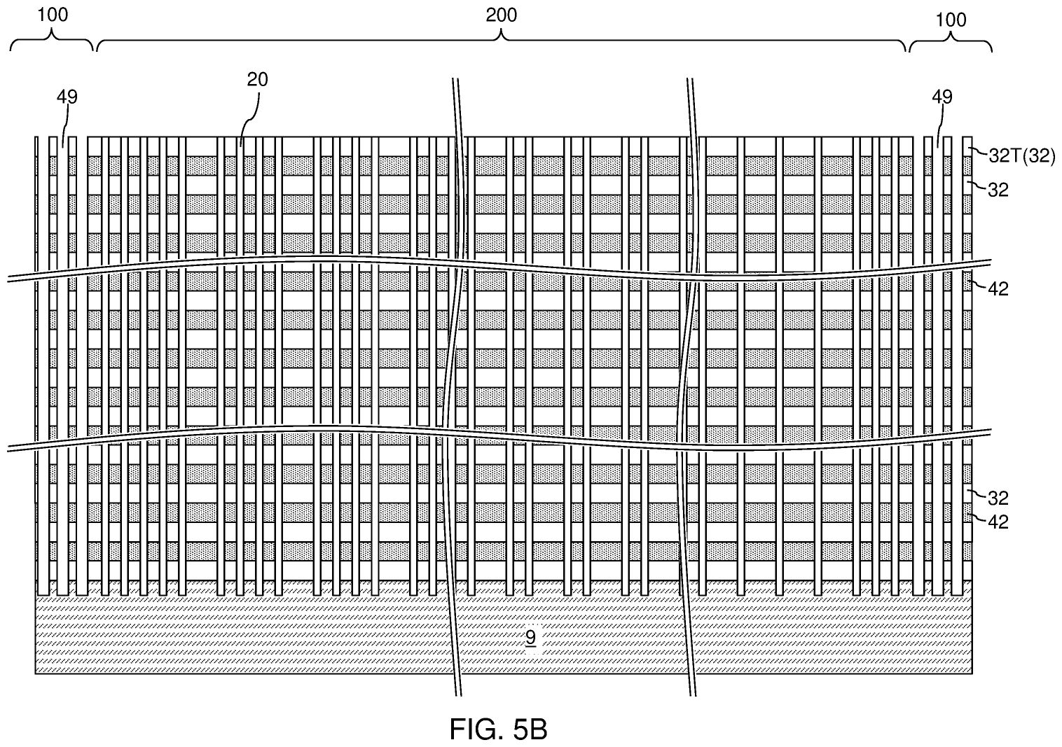

Referring to FIGS. 5A and 5B, the sacrificial memory opening fill structures 47 can be removed selective to the materials of the alternating stack (32, 42) and the semiconductor material layer 9 by performing a selective removal process, which may comprise an ashing process or a selective etch process (which may comprise a dry etch process or a wet etch process). Voids are formed in the volumes of the memory openings 49.

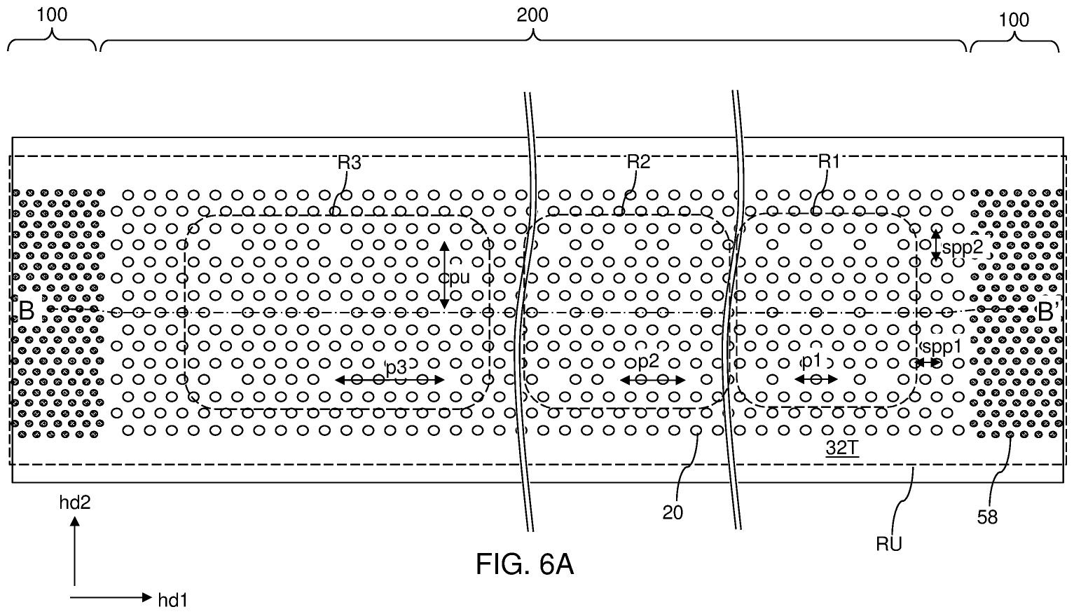

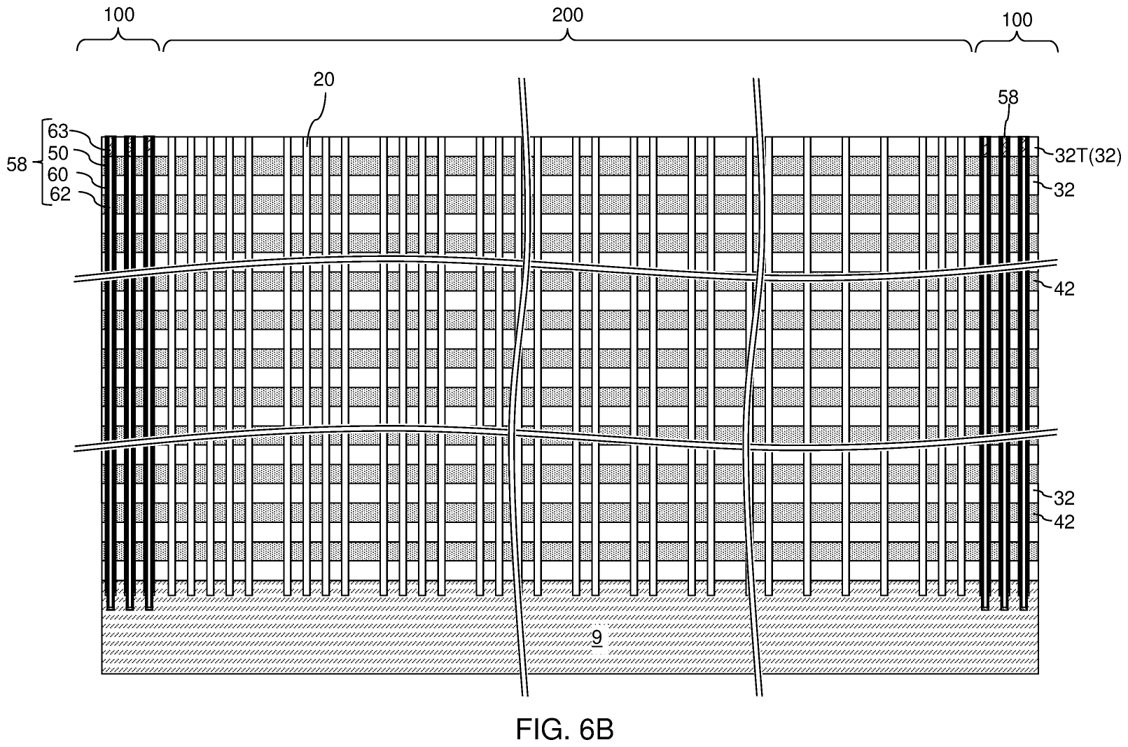

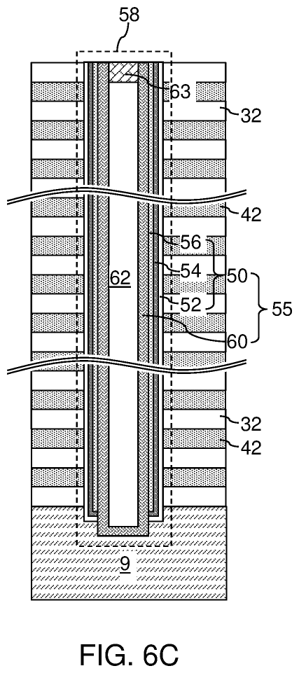

Referring to FIGS. 6A-6C, a memory opening fill structure 58 can be formed within each memory opening 49. For example, a memory film 50 can be formed in a peripheral region of each memory opening 49 by performing at least one conformal deposition process. In one embodiment shown in FIG. 6C, the memory film 50 may include a layer stack of a blocking dielectric layer 52, a memory material layer 54 (which may comprise a charge storage layer, such as a silicon nitride layer, or any alternative type of memory material layer, such as a ferroelectric material layer), and an optional dielectric liner 56 (such as a tunneling dielectric layer). Generally, the memory film 50 comprises a vertical stack of memory elements, which may be located at levels of the sacrificial material layers 42. For example, portions of a charge material layer located at the levels of the sacrificial material layers constitute charge storage material portions, which are memory elements. An optional anisotropic etch process may be performed to remove horizontally-extending portions of the memory film 50, for example, at the bottom of each memory opening 49 and from above the alternating stack (32, 42). A vertical semiconductor channel 60 and a dielectric core 62 can be formed in an inner region of each memory opening 49. The vertical semiconductor channels 60 may comprise a polysilicon or an amorphous silicon layer have a doping of a first conductivity type. A drain region 63 having a doping of a second conductivity type may be formed at an upper end of each vertical semiconductor channel 60. The combination of the memory film 50 and the vertical semiconductor channel 60 within each memory opening 49 constitutes a memory stack structure 55. The set of all material portions filling a memory opening 49 constitutes a memory opening fill structure 58. Each of the memory opening fill structures 58 comprises a respective vertical stack of memory elements.

In another alternative embodiment, the steps described above with respect to FIGS. 3A, 3B, 4A and 4B are omitted. In this alternative embodiment, dummy memory opening fill structures are formed in the support openings 19 at the same time as the memory opening fill structures 58 are formed in the memory openings. The dummy memory opening fill structures function as the support pillar structures 20, and are electrically inactive. In other words, they are not electrically connected to bit lines to be formed during a subsequent step.

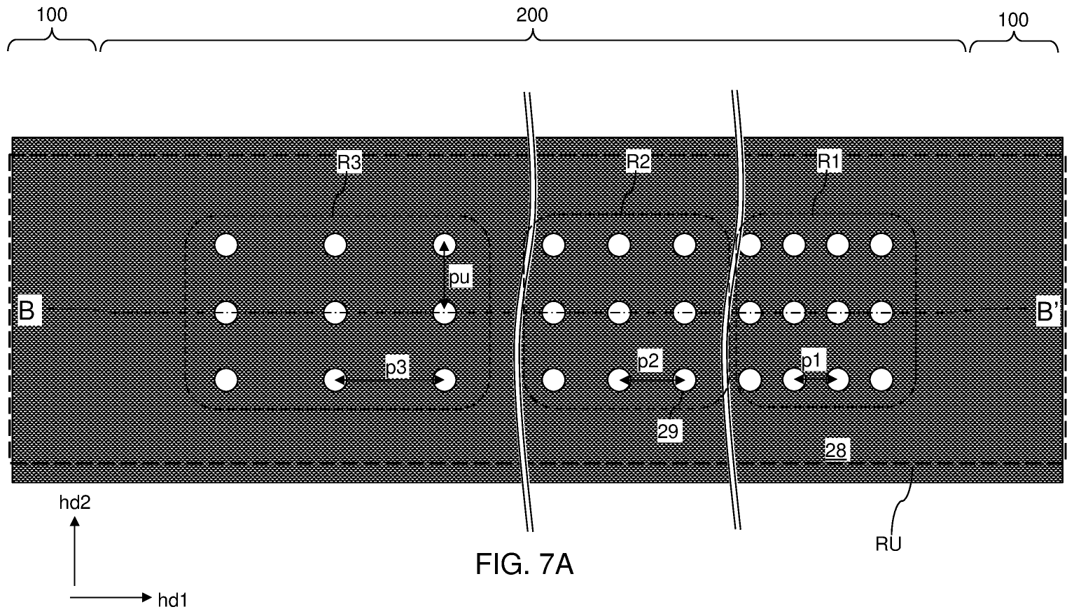

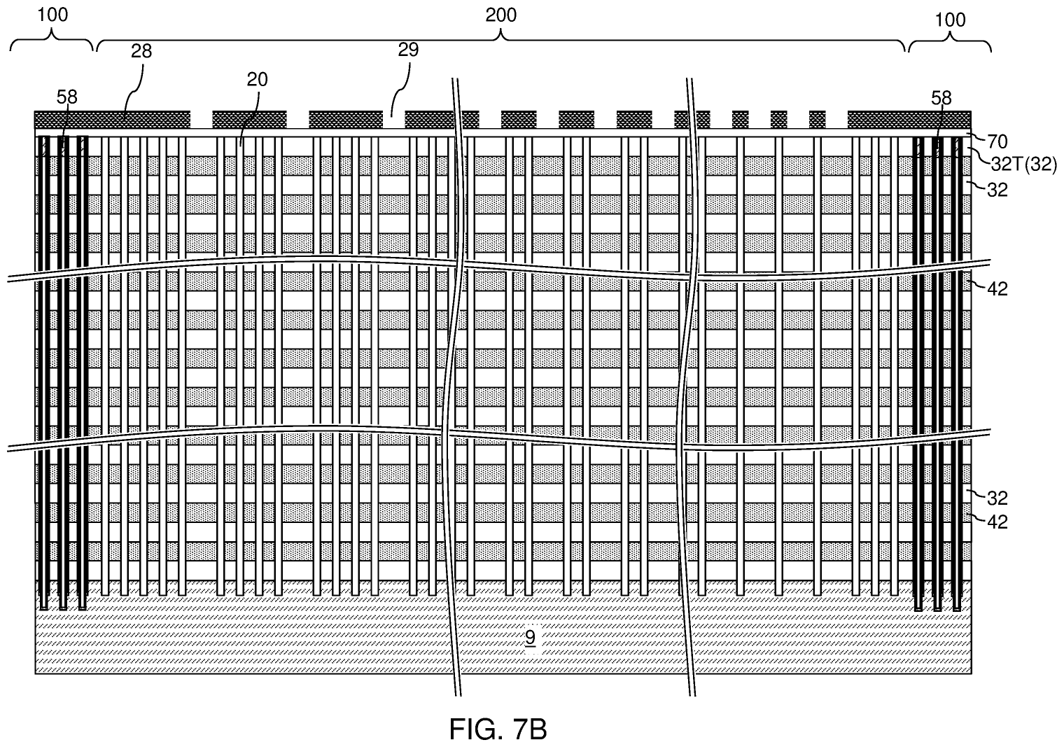

Referring to FIGS. 7A and 7B, an insulating cap layer 70 and a patterned hard mask layer 28 can be formed over the alternating stack (32, 42). The insulating cap layer 70 comprises an insulating material, such as silicon oxide. The thickness of the insulating cap layer 70 may be in a range from 10 nm to 300 nm, such as from 20 nm to 150 nm, although lesser and greater thicknesses may also be employed. The patterned hard mask layer 28 comprises a hard mask material that can function as an etch mask material during subsequent anisotropic etch processes to be employed to etch materials of the insulating layers 32 and the sacrificial material layers 42. For example, the hard mask material of the patterned hard mask layer 28 may comprise a metallic material such as TiN, TaN, WN, MON, Ti, Ta, W, Mo, or a combination thereof.

The patterned hard mask layer 28 may be formed by depositing a blanket hard mask layer (i.e., an unpatterned hard mask layer), and by patterning the blanket hard mask layer. For example, a photoresist layer (not shown) can be deposited over the blanket hard mask layer, and can be lithographically patterned to form openings at locations of the complementary subset of the lattice sites of the first periodic two-dimensional array described above. An anisotropic etch process can be performed to transfer the pattern of the openings in the photoresist layer through the blanket hard mask layer, thereby converting the blanket hard mask layer into the patterned hard mask layer 28. The patterned hard mask layer 28 may comprise arrays of openings 29 therethrough.

In one embodiment, the exemplary structure comprises a first region R1 including a first two-dimensional array of a first subset of the openings 29 having the first periodic pitch p1 along the first horizontal periodicity direction, a second region R2 including a second two-dimensional array of a second subset of the openings 29 having the second periodic pitch p2 along the first horizontal periodicity direction, and a third region R3 including a third two-dimensional array of a third subset of the openings 29 having the third periodic pitch p3. In one embodiment, the second periodic pitch p2 is greater than the first periodic pitch p1, and the third periodic pitch p3 is greater than the second periodic pitch p2. In one embodiment, the ratio of the second periodic pitch p2 to the first periodic pitch p1 is in a range from 1.2 to 2, and the ratio of the third periodic pitch p3 to the second periodic pitch p2 is in a range from 1.2 to 2. In an alternative embodiment, all openings 29 have the same pitch throughout the contact region 200.

In one embodiment, the first horizontal periodicity direction is the first horizontal direction hd1. In one embodiment, the first two-dimensional array comprises a first two-dimensional periodic array having a uniform pitch pu along the second horizontal periodicity direction that is different from the first horizontal periodicity direction, and the second two-dimensional array comprises a second two-dimensional periodic array having the uniform pitch pu along the second horizontal periodicity direction. In one embodiment, the quasi-periodic two-dimensional array of support pillar structures 20 vertically extends through the alternating stack (32, 42). The support pillar structures 20 in the quasi-periodic two-dimensional array are located at a primary subset of lattice sites of a first periodic two-dimensional array having the first support-pillar periodicity along the first horizontal direction hd1 and having the second support-pillar periodicity along the second horizontal direction hd2 in a plan view. The openings 29 in the patterned hard mask layer 28 may be located at a complementary subset of the vacancy lattice sites of the first periodic two-dimensional array.

In one embodiment, the second region R2 is laterally spaced from the first region R1 along the first horizontal direction hd1, and the third region R3 is laterally spaced from the second region R2 along the first horizontal direction hd1. In one embodiment, the first horizontal direction hd1 is parallel to the first horizontal periodicity direction, and the second horizontal direction hd2 is perpendicular to the first horizontal periodicity direction.

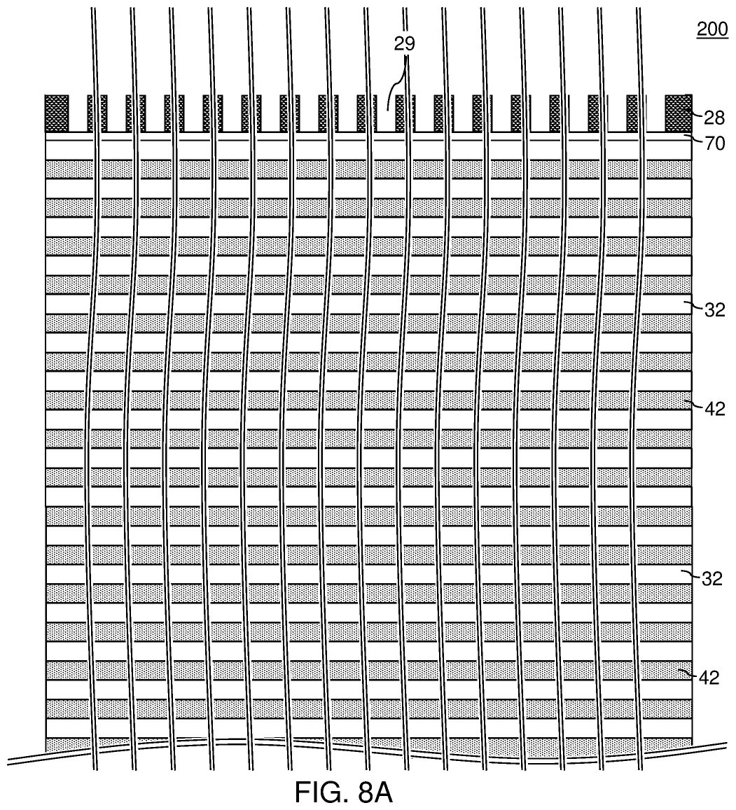

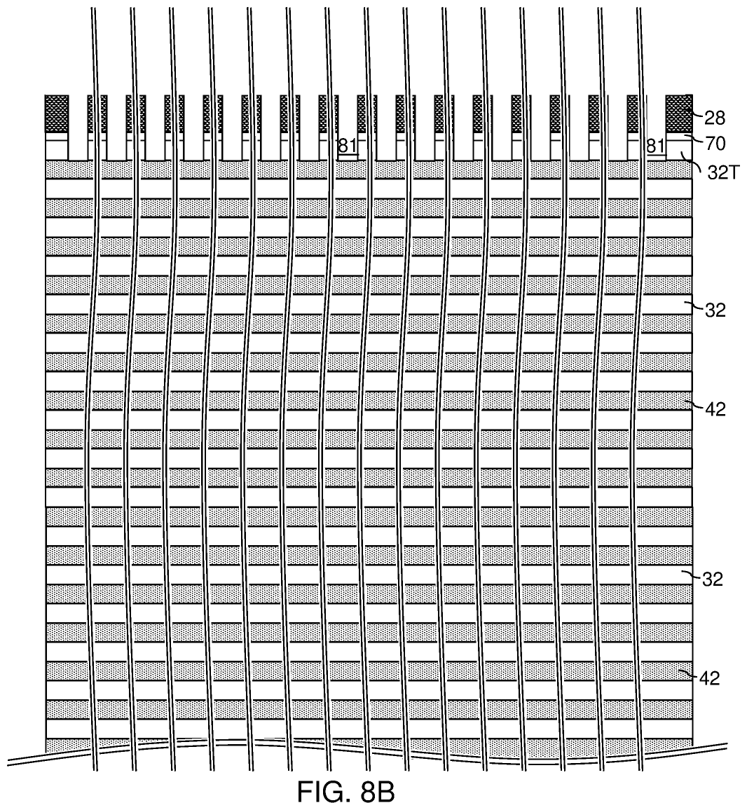

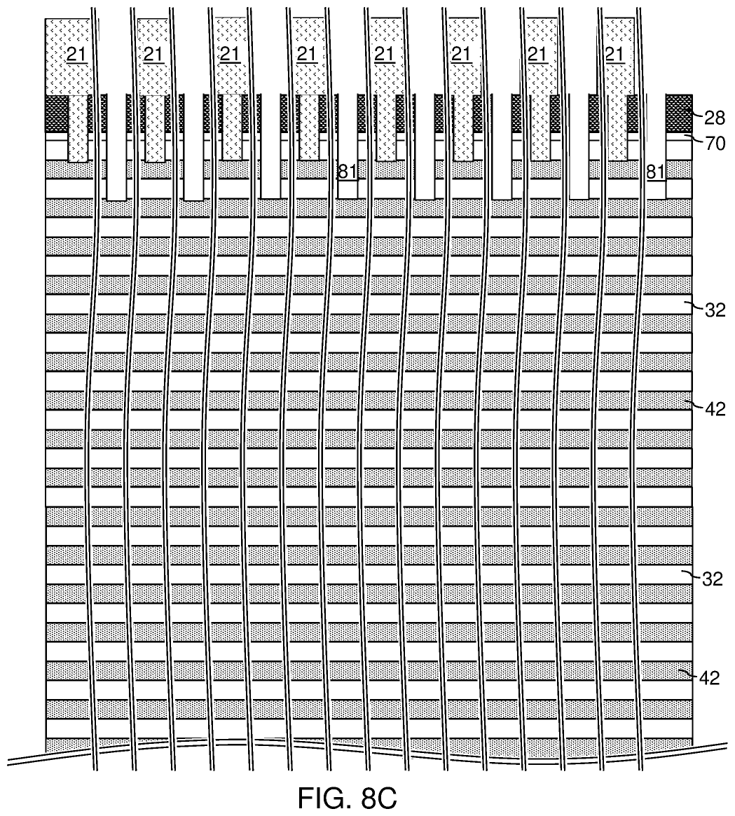

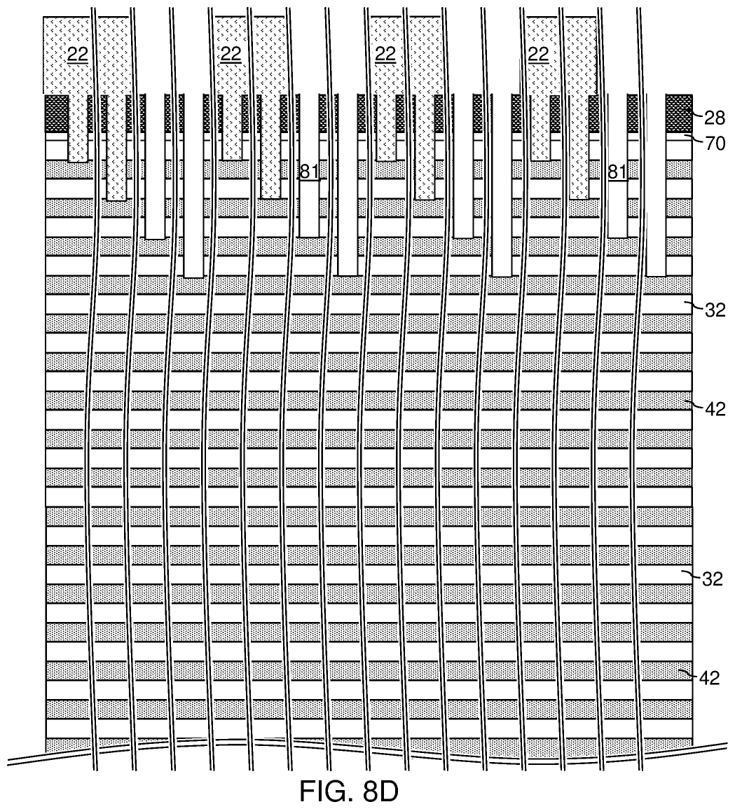

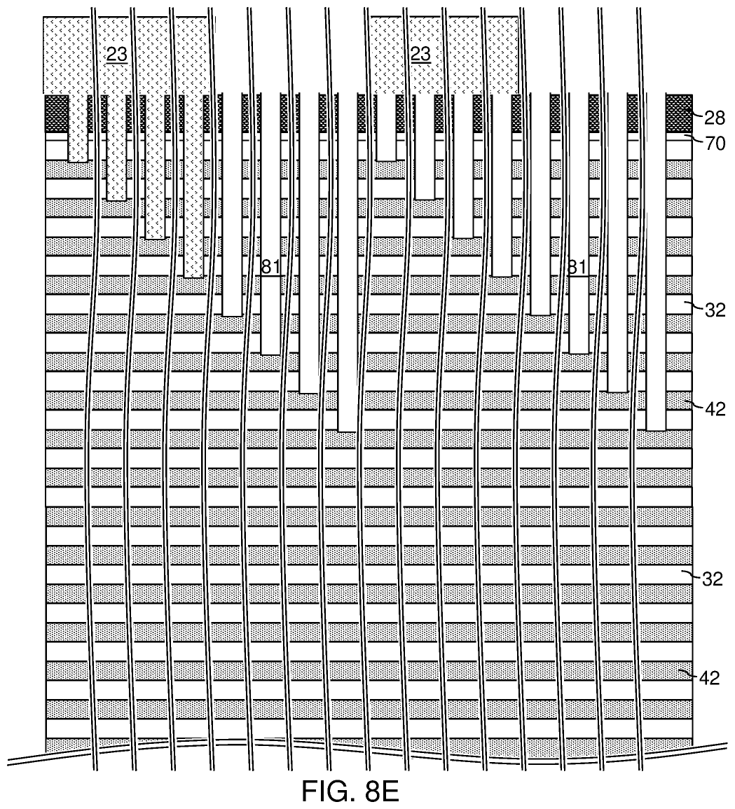

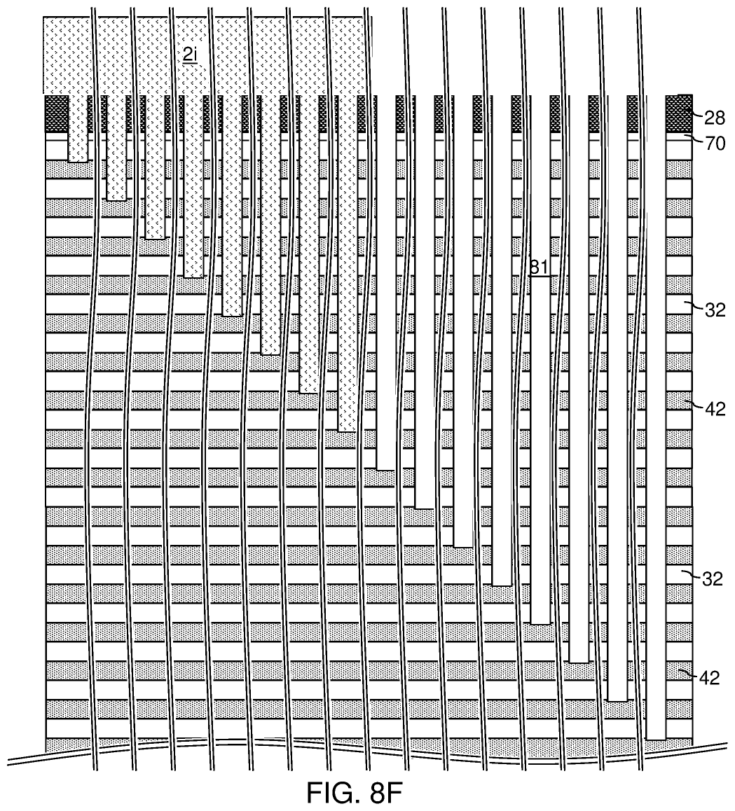

FIGS. 8A-8F are sequential schematic vertical cross-sectional view of region of the exemplary structure during formation of contact via openings 81 according to an embodiment of the present disclosure.

Referring to FIG. 8A, a portion of the contact region 200 in the exemplary structure of FIGS. 7A and 7B is illustrated.

Referring to FIG. 8B, an anisotropic etch process (which is also referred to as an initial anisotropic etch process) can be performed to etch through the topmost first-tier insulating layer 32T underneath the openings in the patterned hard mask layer 28. Via cavities can be formed through the topmost insulating layer 32T. The via cavities are herein referred to as contact via openings 81.

Referring to FIG. 8C, a first photoresist layer 21 can be applied over the patterned hard mask layer 28, and can be lithographically patterned to form openings in areas of a first primary subset of the contact via openings 81 without covering areas of a first complementary subset of the contact via openings 81. About one half of all of the contact via openings 81 can be covered the first photoresist layer 21. The first complementary subset of the contact via openings 81 can be vertically extended through the alternating stack by a first vertical extension distance, which can be the same as the sum of a thickness of an insulating layers 32 and a sacrificial material layer 42. The first photoresist layer 21 can be subsequently removed, for example, by ashing.

Referring to FIG. 8D, a second photoresist layer 22 can be applied over the patterned hard mask layer 28, and can be lithographically patterned to form openings in areas of a second primary subset of the contact via openings 81 without covering areas of a second complementary subset of the contact via openings 81. About one half of all of the contact via openings 81 can be covered the second photoresist layer 22. In one embodiment, the pattern of the second photoresist layer 22 can be selected such that four types of openings 29 in the patterned hard mask layer 28 are provided depending on whether an opening 29 is covered by first photoresist layer 21 at the processing steps of FIG. 8C and depending on whether the opening 29 is covered by the second photoresist layer 22 at the processing steps of FIG. 8D. The second complementary subset of the contact via openings 81 can be vertically extended through the alternating stack by a second vertical extension distance, which can be twice the sum of a thickness of an insulating layers 32 and a sacrificial material layer 42. The second photoresist layer 22 can be subsequently removed, for example, by ashing.

Referring to FIG. 8E, a third photoresist layer 23 can be applied over the patterned hard mask layer 28, and can be lithographically patterned to form openings in areas of a third primary subset of the contact via openings 81 without covering areas of a third complementary subset of the contact via openings 81. About one half of all of the contact via openings 81 can be covered the third photoresist layer 23. In one embodiment, the pattern of the third photoresist layer 23 can be selected such that up to eight types of openings 29 in the patterned hard mask layer 28 are provided depending on whether an opening 29 is covered by first photoresist layer 21 at the processing steps of FIG. 8C, depending on whether the opening 29 is covered by the second photoresist layer 22 at the processing steps of FIG. 8D, and depending on whether the openings 29 is covered by the third photoresist layer 23 at the processing steps of FIG. 8E. The third complementary subset of the contact via openings 81 can be vertically extended through the alternating stack by a third vertical extension distance, which may be four times the sum of a thickness of an insulating layers 32 and a sacrificial material layer 42. The third photoresist layer 23 can be subsequently removed, for example, by ashing.

Referring to FIG. 8F, the processing steps described with reference to FIGS. 8C-8E may be repeated with suitable modifications in the pattern of a photoresist layer and the anisotropic etch depth. Generally, for each integer i in a range from 1 to N, in which N is an integer in a range from 3 to 10 and i is a positive integer not greater than N, an i-th photoresist layer 2i can be applied over the patterned hard mask layer 28, and can be lithographically patterned to form openings in areas of an i-th primary subset of the contact via openings 81 without covering areas of an i-th complementary subset of the contact via openings 81. About one half of all of the contact via openings 81 can be covered the i-th photoresist layer 2i. In one embodiment, the pattern of the i-th photoresist layer 2i can be selected such that up to 2ⁱ types of openings 29 in the patterned hard mask layer 28 are provided depending on whether an opening 29 is covered by each photoresist layer including the first photoresist layer and up to the i-th photoresist layer 2i. The i-th complementary subset of the contact via openings 81 can be vertically extended through the alternating stack by an i-th vertical extension distance, which can be an integer multiple of the sum of a thickness of an insulating layers 32 and a sacrificial material layer 42. The integer multiple may be a number that may be equal to, or may be less than, 2⁽ⁱ⁻¹⁾. The i-th photoresist layer 2i can be subsequently removed, for example, by ashing.

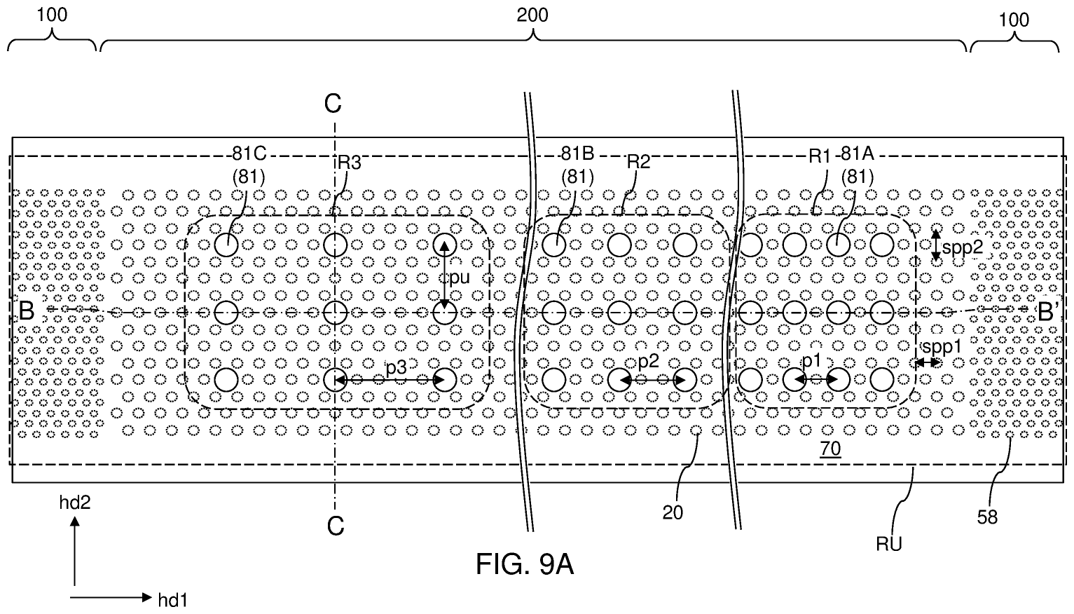

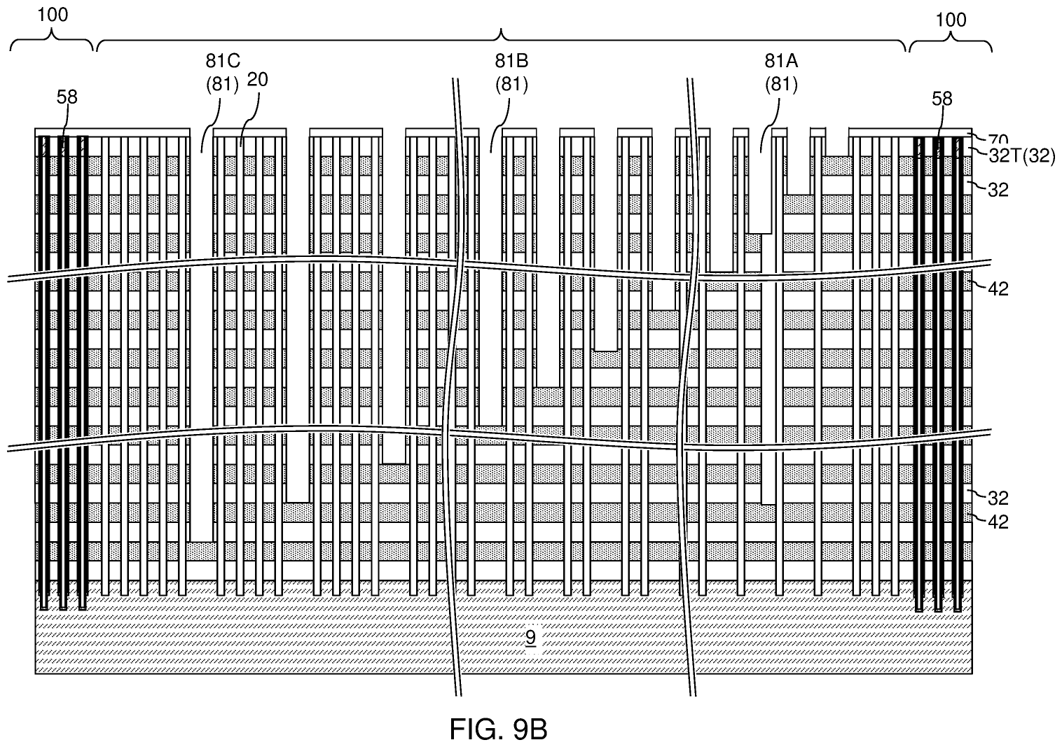

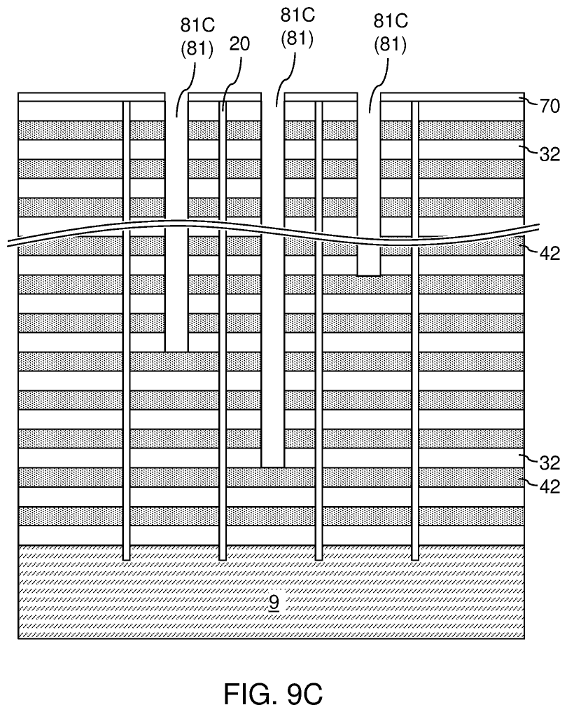

Referring to FIGS. 9A-9C, the exemplary structure is illustrated after performing the N-th anisotropic etch process. The contact via openings 81 may have up to 2^{N} different depths. The patterned hard mask layer 28 can be subsequently removed, for example, by performing a selective etch process that etches the material of the patterned hard mask layer 28 selective to the materials of the insulating layers 32 and the sacrificial material layers 42. Generally, the pattern of the photoresist layers (21, 22, 23, etc.) can be selected such that a first subset of the contact via openings 81 formed within the first region R1 has a first average depth, a second subset of the contact via openings 81 formed within the second region R2 has a second average depth greater than the first average depth, and a third subset of the contact via openings 81 formed within the third region R3 has a third average depth greater than the second average depth, as shown in FIG. 9B. The first subset of the contact via openings 81 is herein referred to as first contact via openings 81A, the second subset of the contact via openings 81 is herein referred to as second contact via openings 81B, and the third subset of the contact via openings 81 is herein referred to as third contact via openings 81C. In one embodiment, the maximum depth of the first contact via openings 81A may be less than the minimum depth of the second contact via openings 81B, and the maximum depth of the second contact via openings 81B may be less than the minimum depth of the third contact via openings 81C. In one embodiments, the first contact via openings 81A have a shallower average depth than the second contact via openings 81B, and the second contact via openings 81B may be have a shallower average depth average depth than the third contact via openings 81C. The shallower first contact via openings 81A in the first region R1 have a smaller pitch (i.e., a higher density per unit area) than the deeper second contact openings 81B in the second region R2. The shallower second contact via openings 81B in the second region R1 have a smaller pitch (i.e., a higher density per unit area) than the deeper third contact openings 81C in the third region R3.

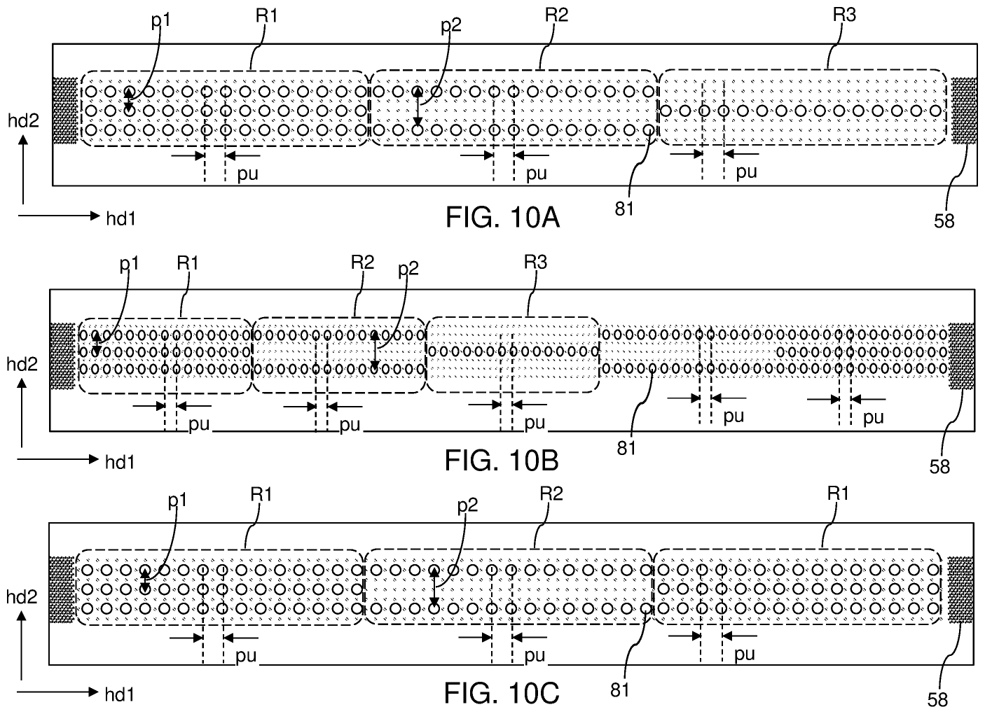

FIGS. 10A-10C are top-down views of alternative configuration of the exemplary structure after the processing steps of FIGS. 9A-9C according to an alternative embodiment of the present disclosure. In the alternative configurations of the exemplary structure, the first horizontal periodicity direction along which a first subset of the contact via openings 81 has a first periodic pitch p1, a second subset of the contact via openings 81 has a second periodic pitch p2, and a third subset of the contact via openings 81 has a third periodic pitch p3 can be the second horizontal direction hd2. Further, the second horizontal periodicity direction along which the first subset of the contact via openings 81, the second subset of the contact via openings 81, and the third subset of the contact via openings 81 have the uniform pitch pu may be the first horizontal direction hd1.

In other words, in this alternative embodiment, there may be more rows of shallower first contact via openings 81A extending along the first horizontal direction hd1 in the first region R1 than of the deeper second contact via openings 81B in the second region R2. There also may be more rows of shallower second contact via openings 81B in the second region R2 than of the deeper third contact via openings 81C in the third region R3. Therefore, in this alternative embodiment, the shallower contact via openings also have a higher density per unit area than the deeper contact via openings.

Referring collectively to FIGS. 9A-9C and 10A-10C, an array of contact via openings 81 can be formed such that each of the contact via openings 81 is formed on a respective one of the sacrificial material layers 42 and vertically extends through a respective subset of layers within the alternating stack (32, 42) that overlies the respective one of the sacrificial material layers 42. In one embodiment, the exemplary structure comprises a first region R1 including a first two-dimensional array of a first subset of the contact via openings 81 that has a first average height and a first periodic pitch p1 along a first horizontal periodicity direction; a second region R2 including a second two-dimensional array of a second subset of the contact via openings 81 having a second average height and a second periodic pitch p2 along the first horizontal periodicity direction; and optionally a third region R3 including a third two-dimensional array of a third subset of the contact via openings 81 having a third average height and a third periodic pitch p3 along the first horizontal periodicity direction. The second average height is greater than the first average height; and the third average height is greater than the second average height. The second periodic pitch p2 is greater than the first periodic pitch p1, and the third periodic pitch p3 is greater than the second periodic pitch p2. Therefore, the shallower contact via openings have a higher density per unit area than the deeper contact via openings.

In one embodiment, a cavity-volume to region-area ratio of a total volume of the contact via openings 81 within a selected region (R1, R2, R3) to the total area of the selected region (R1, R2, R3) is about the same (i.e., within 30% of each other, such as within 20% of each other, such as within 0 to 10% of each other). In other words, the cavity-volume to region area ratios across the first region R1, the second region R2, and the third region R3 may be about the same. Thus, each value of the cavity-volume to region-area ratios for the first region R1, the second region R2, and the third region R3 may be between 0.7 and 1.3 times (e.g., between 0.8 and 1.2 times, such as between 0.9 and 1.1 times) the average of the cavity-volume to region area ratios of the first region R1, the second region R2, and the third region R3.

According to an embodiment of the present disclosure, the relative uniformity of the cavity-volume to region-area ratios for the various regions in the contact region 200 (such as the first region R1, the second region R2, and the third region R3) provides the benefit of reducing a photoresist sucking effect during the processing steps described with reference to FIGS. 8C-8F, i.e., the processing steps employed to form the contact via openings 81A. Specifically, application of the photoresist layers (21, 22, 23, 2i), especially for the photoresist layers that are formed closer toward the final patterning steps for formation of the contact via openings 81, causes a photoresist material to be sucked into the voids within the contact via openings 81. Local thickness reduction of the photoresist material occurs around deep contact via openings 81. Typically, more photoresist is sucked into the deeper openings than the shallow openings, which causes the top surface of the photoresist layer to become uneven. This degrades the quality of the exposure of the photoresist layer. According to an aspect of the present disclosure, the areal density of the contact via openings 81 can be reduced around a subset of the deeper contact via openings 81, such as the third contact via openings 81C, so that the effect of photoresist sucking into the deeper (i.e., higher volume) openings is reduced. In areas in which the areal density of the contact via openings 81 is low, such as the first region R1 including the shallower first contact via openings 81A, the areal density of the contact via openings 81 can be high so that the overall device density of a three-dimensional memory device to be subsequently formed can be increased.

In one embodiment, the exemplary structures illustrated in FIGS. 9A-9C and 10A-10C, comprise a quasi-periodic two-dimensional array of support pillar structures 20 vertically extending through the alternating stack (32, 42). The support pillar structures 20 in the quasi-periodic two-dimensional array are located at a primary subset of lattice sites of a first periodic two-dimensional array having a first support-pillar periodicity spp1 along a first horizontal direction hd1 and having a second support-pillar periodicity spp2 along a second horizontal direction hd2 in a plan view. The contact via openings 81 are located at a complementary subset of the vacancy lattice sites of the first periodic two-dimensional array, and do not extend through the support pillar structures 20. In one embodiment, the second region R2 is laterally spaced from the first region R1 along the first horizontal direction hd1, and the third region R3 is laterally spaced from the second region R2 along the first horizontal direction hd1. In one embodiment, the first horizontal direction hd1 is parallel to the first horizontal periodicity direction, and the second horizontal direction hd2 is perpendicular to the first horizontal periodicity direction. In one embodiment, the first subset of the contact via openings 81 is formed at the vacancy lattice sites of a first subset of the complementary subset in the first region R1; and the second subset of the contact via openings 81 is formed at the vacancy lattice sites of a second subset of the complementary subset in the second region R2.

In an alternative embodiment, the support pillar structures 20 are arranged in a periodic two-dimensional array. In this alternative embodiment, some of the contact via openings 81 may extend through the support pillar structures 20 due to the different density of the contact via openings 81 which does not match the spacing of the periodic two-dimensional array of the support pillar structures 20.

In one embodiment, each of the contact via openings 81 contacts a respective one of the sacrificial material layers 42 and vertically extends through a respective subset of layers within the alternating stack (32, 42) that overlies the respective one of the sacrificial material layers 42. In one embodiment, the three-dimensional memory device comprises a first region R1 including a first two-dimensional array of a first subset of the contact via openings 81 that has a first average height and a first periodic pitch p1 along a first horizontal periodicity direction, and further comprises a second region R2 including a second two-dimensional array of a second subset of the contact via openings 81 having a second average height and a second periodic pitch p2 along the first horizontal periodicity direction. The second average height is greater than the first average height, and the second periodic pitch p2 is greater than the first periodic pitch p1.

In one embodiment, a ratio of the second average height to the first average height is in a range from 1.5 to 3; and a ratio of the second periodic pitch p2 to the first periodic pitch p1 is in a range from 1.2 to 2. In one embodiment, the first horizontal periodicity direction is the first horizontal direction hd1, as illustrated in FIGS. 9A-9C. In another embodiment, the first horizontal periodicity direction is the second horizontal direction hd2, as illustrated in FIGS. 10A-10C. In one embodiment, the first horizontal direction hd1 is parallel to the first horizontal periodicity direction; and the second horizontal direction hd2 is perpendicular to the first horizontal periodicity direction, as illustrated in FIGS. 9A-9C. In this embodiment, the first periodic pitch p1 is a first multiple, such as a first integer multiple of the first support-pillar periodicity spp1; and the second periodic pitch p2 is a second multiple, such as a second integer multiple of the first support-pillar periodicity spp1 as illustrated in FIGS. 10A-10C.

In one embodiment, the first two-dimensional array comprises a first two-dimensional periodic array of the first subset of the contact via openings 81 having a uniform pitch pu along a second horizontal periodicity direction that is different from the first horizontal periodicity direction; and the second two-dimensional array of the second subset of the contact via openings 81 comprises a second two-dimensional periodic array having the uniform pitch pu along the second horizontal periodicity direction.

In one embodiment, the first periodic pitch p1 is a first integer multiple of the second support-pillar periodicity spp2; and the second periodic pitch p2 is a second integer multiple of the second support-pillar periodicity spp2. In one embodiment, the first subset of the contact via openings 81 is located at lattice sites of a first subset of the complementary subset in the first region R1; and the second subset of the contact via openings 81 is located at lattice sites of a second subset of the complementary subset in the second region R2. In one embodiment, the first subset of the complementary subset has a uniform pitch pu along a second horizontal periodicity direction that is different from the first horizontal periodicity direction; and the second subset of the complementary subset has the uniform pitch pu along the second horizontal periodicity direction.

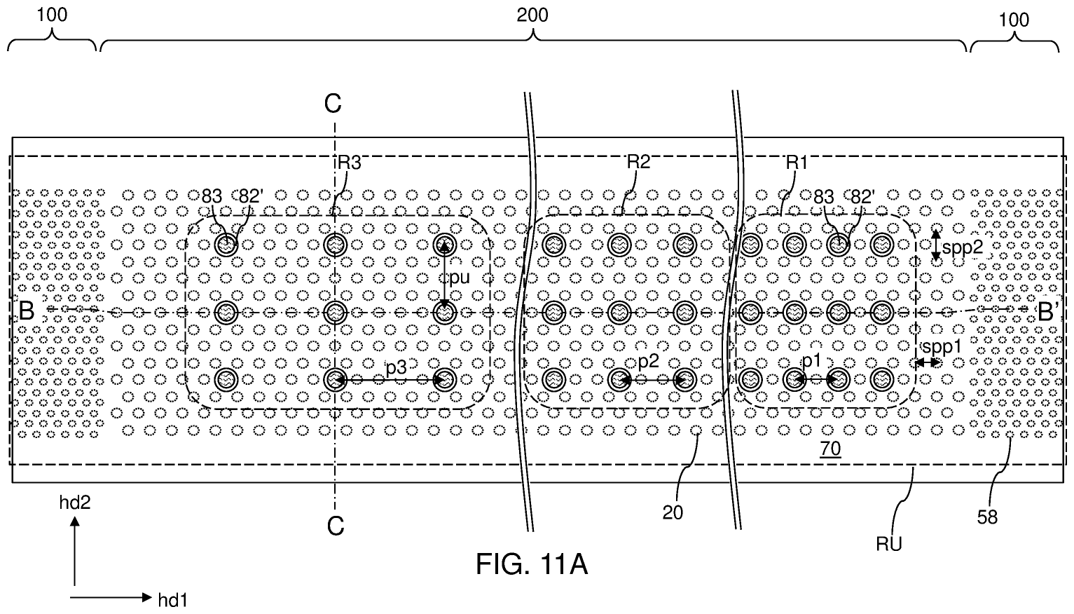

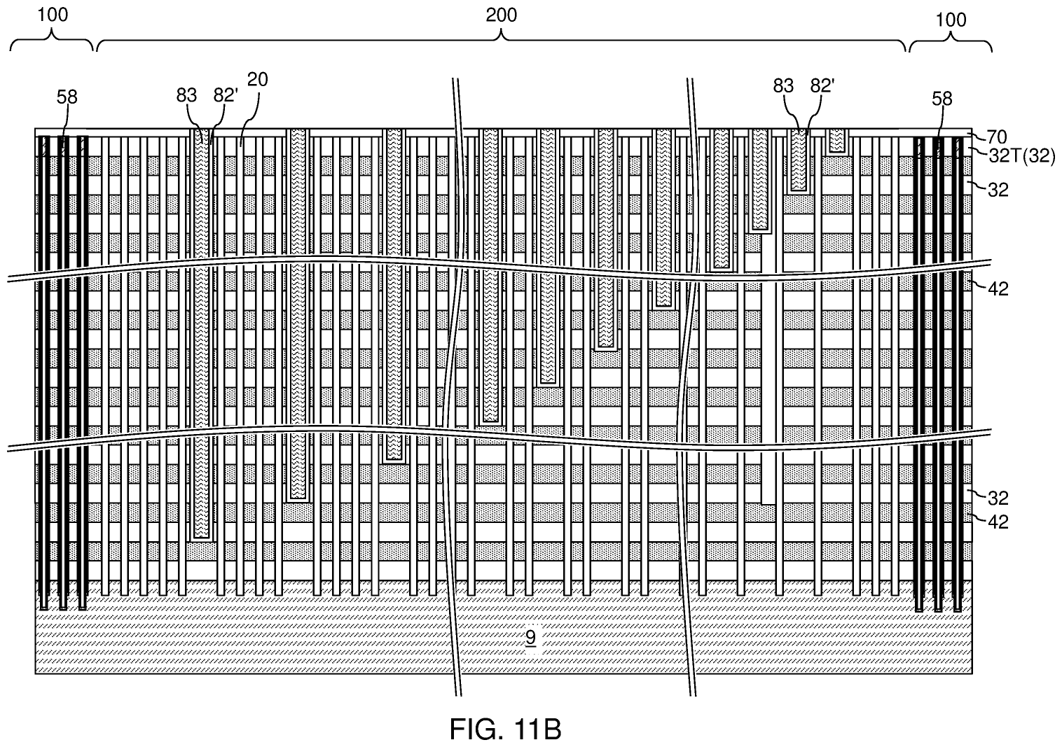

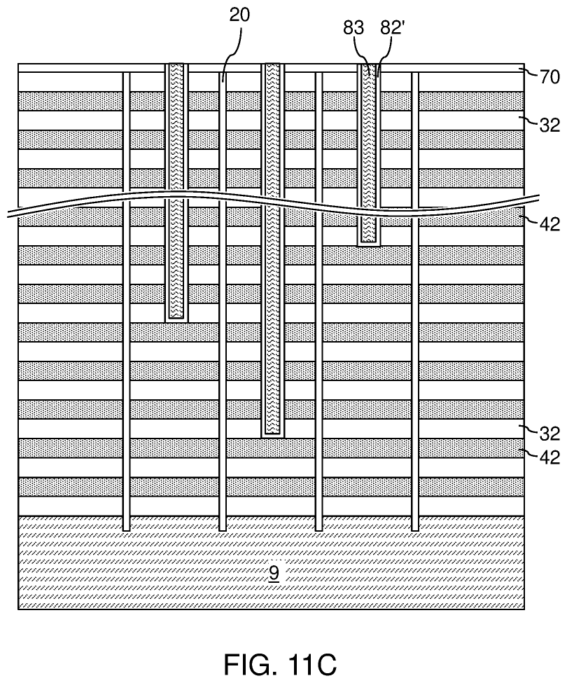

Referring to FIGS. 11A-11C, an insulating material, such as silicon oxide, can be conformally deposited in the contact via openings 89 and over the insulating cap layer 70 to form a conformal insulating material layer. An anisotropic etch process can be performed to remove horizontally-extending portions of the conformal insulating material layer. Each remaining portion of the conformal insulating material layer constitutes an insulating spacer 82′. Each insulating spacer 82′ is a dielectric via liner that contacts a sidewall of a respective one of the contact via openings 81. The insulating spacer 82′ can be formed at a peripheral portion of each contact via opening 81. A contact via cavity can be present within each unfilled volume of the contact via openings 81.

A sacrificial via fill material can be deposited in the contact via cavities, i.e., in the volumes of the contact via openings 81 that are not filled with the insulating spacer 82′. The sacrificial via fill material may comprise a semiconductor material (such as amorphous silicon, polysilicon, or silicon-germanium), a carbon-based material (such as amorphous carbon or diamond-like carbon), an organosilicate glass, or a polymer material. Excess portions of the sacrificial via fill material can be removed from above the horizontal plane including the top surface of the insulating cap layer 70. Each remaining portion of the sacrificial via fill material filling a respective contact via cavity constitutes a sacrificial via opening fill structure 83. Top surface of the sacrificial via opening fill structures 83 may be coplanar with the top surface of the insulating cap layer 70.

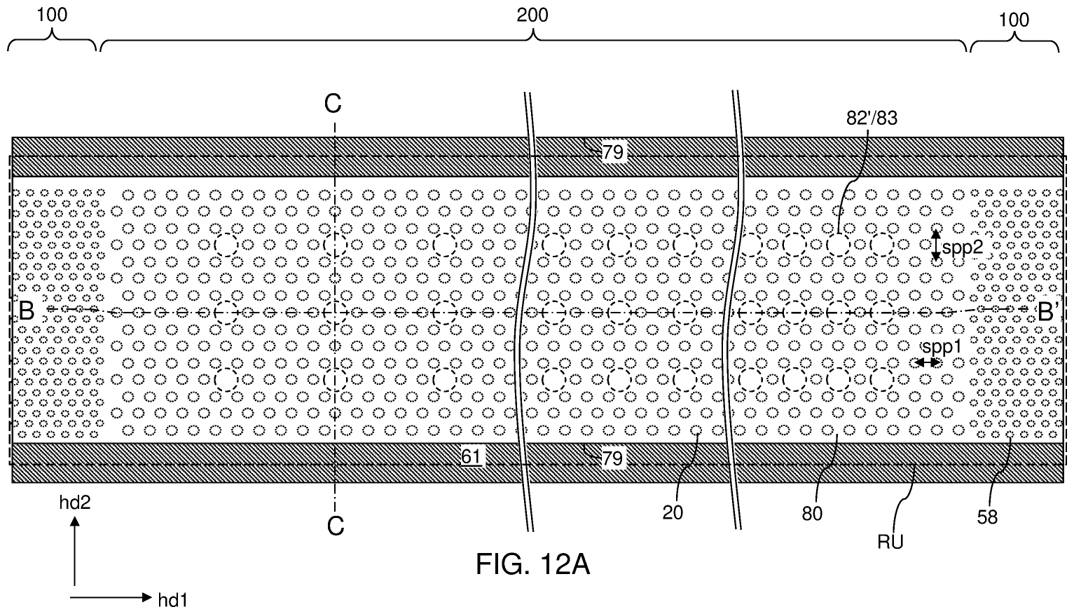

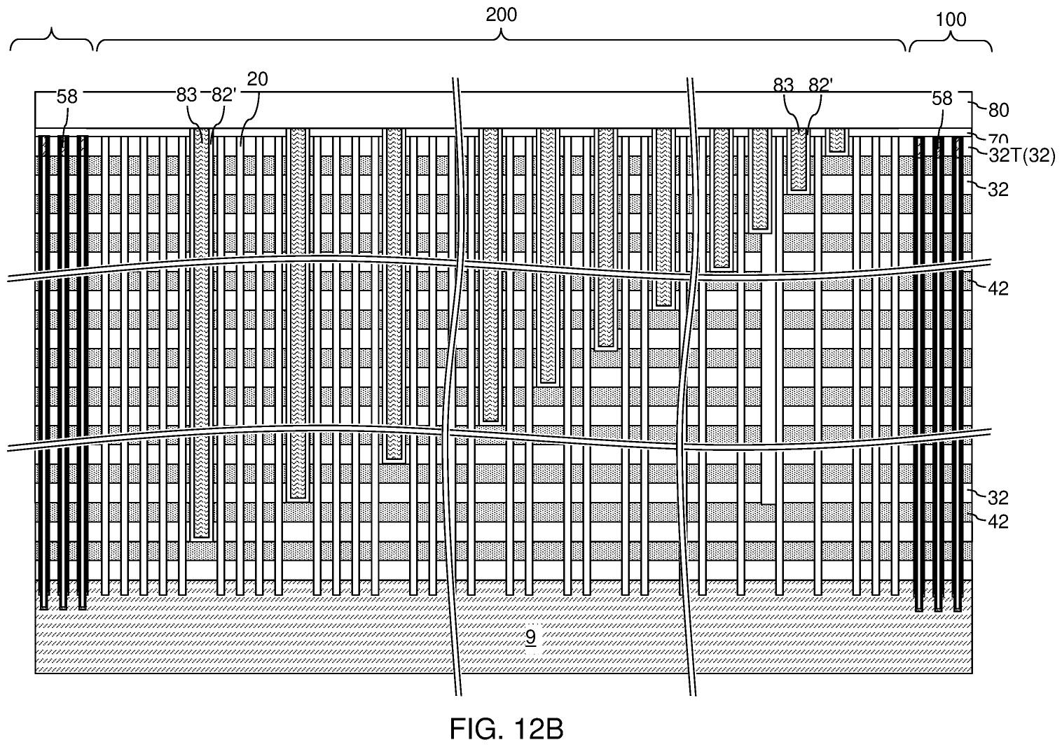

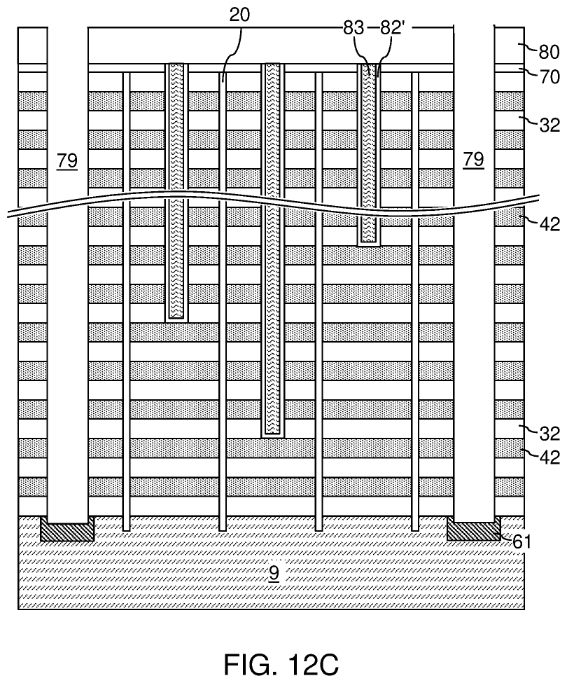

Referring to FIGS. 12A-12C, a dielectric material, such as silicon oxide, can be deposited over the insulating cap layer 70 to form a contact-level dielectric layer 80. A photoresist layer can be applied over the contact-level dielectric layer 80, and can be lithographically patterned to form various elongated openings therethrough. The elongated openings in the photoresist layer may comprise slit-shaped openings that are formed at or around the boundaries between neighboring pairs of repetition units (e.g., memory blocks) RU at which the memory opening fill structures 58 and the support pillar structures 20 are not present.

An anisotropic etch process can be performed to transfer the pattern of the elongated openings in the photoresist layer through the contact-level dielectric layer 80 and the alternating stack of insulating layers 32 and sacrificial material layers 42 and optionally into an upper portion of the semiconductor material layer 9. Lateral isolation trenches 79 are formed underneath the slit-shaped openings in the photoresist layer. The lateral isolation trenches 79 are formed between a respective cluster of memory openings 49 to separate laterally adjacent memory blocks. The lateral isolation trenches 79 laterally extend along the first horizontal direction hd1. Generally, a pair of lateral isolation trenches 79 can laterally extend along a first horizontal direction hd1 through the alternating stacks (32, 42) such that each neighboring pair of alternating stacks (32, 42) are laterally spaced from each other along the second horizontal direction hd2. Source regions 61 may optionally be formed by implanting dopants of the second conductivity type into surface portions of the semiconductor material layer 9 that underlies the lateral isolation trenches 79.

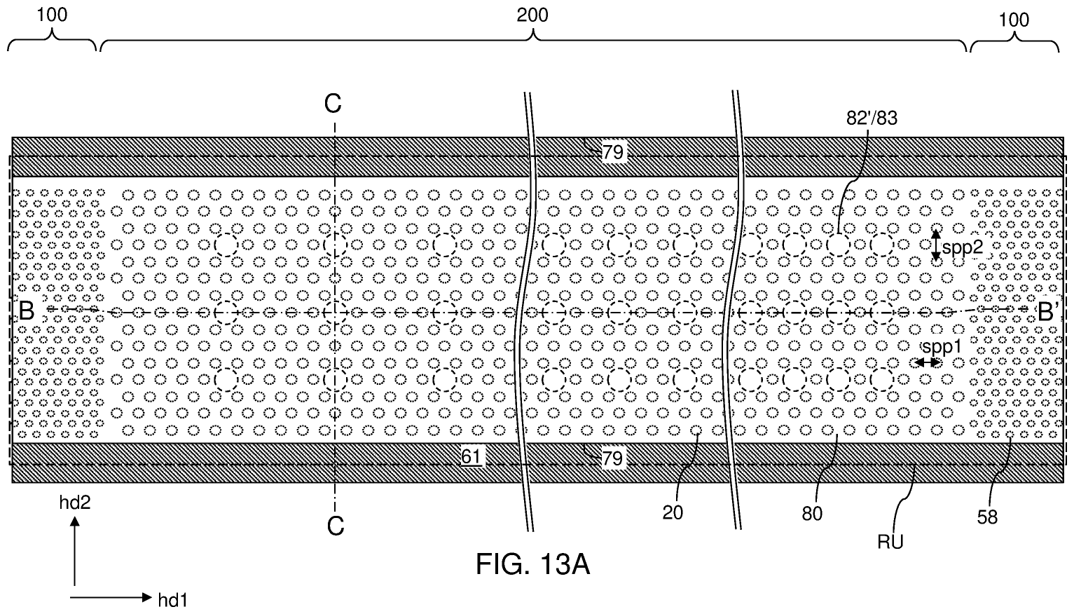

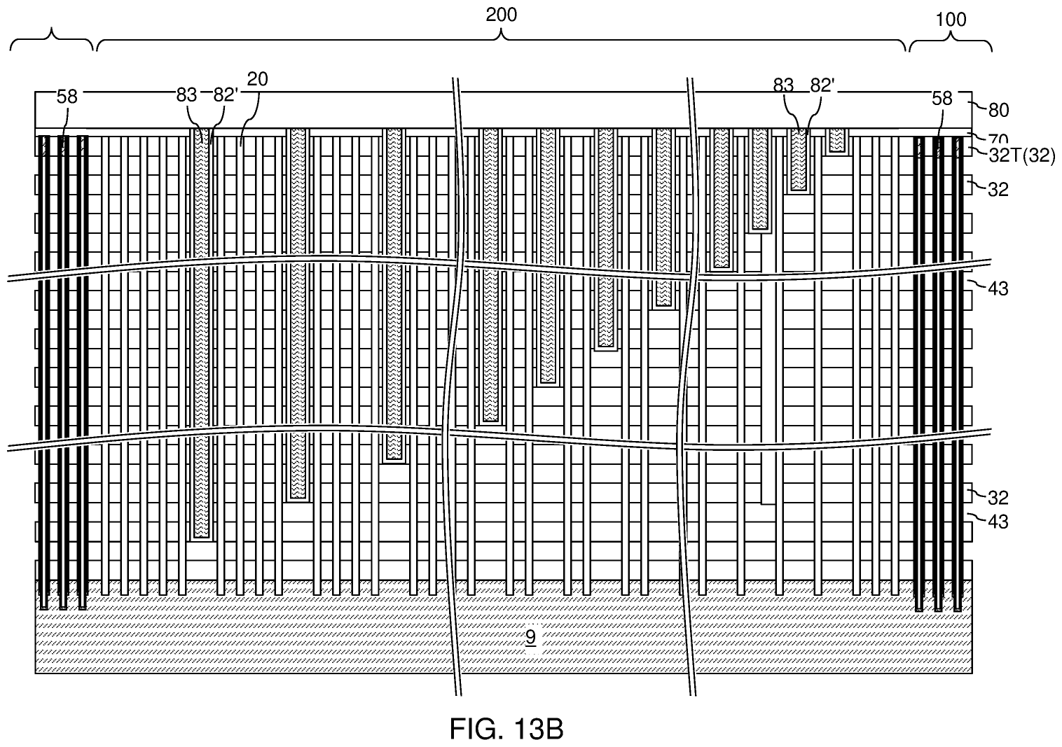

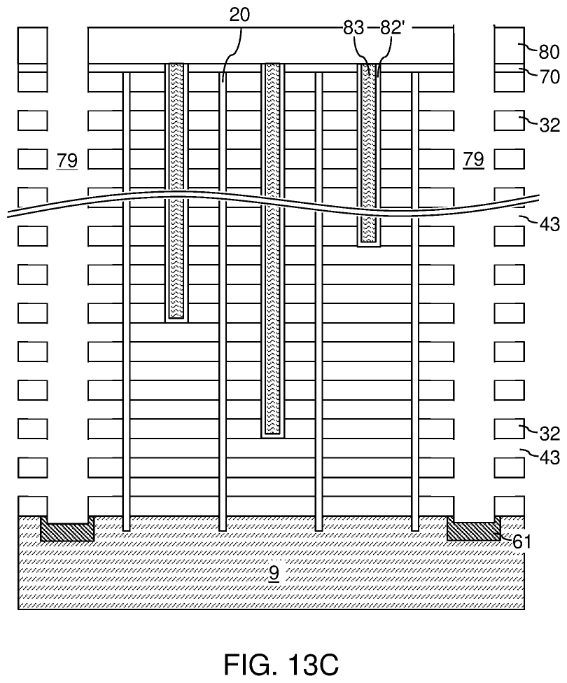

Referring to FIGS. 13A-13C, an isotropic etch process can be performed to etch the material of the sacrificial material layers 42 selective to materials of the insulating layers 32, the insulating spacers 82′, the insulating cap layer 70, the contact-level dielectric layer 80, the outermost layer of each memory film 50 (such as a blocking dielectric layer 52), and the semiconductor material layer 9. For example, if the sacrificial material layers 42 comprise silicon nitride, a wet etch process employing hot phosphoric acid may be performed to remove the sacrificial material layers 42. A laterally-extending cavity 43 can be formed within each void that is formed by removal of a portion of a sacrificial material layer 42. The laterally-extending cavities 43 can be formed around each contiguous combination of a sacrificial via opening fill structure 83 and an insulating spacer 82′.

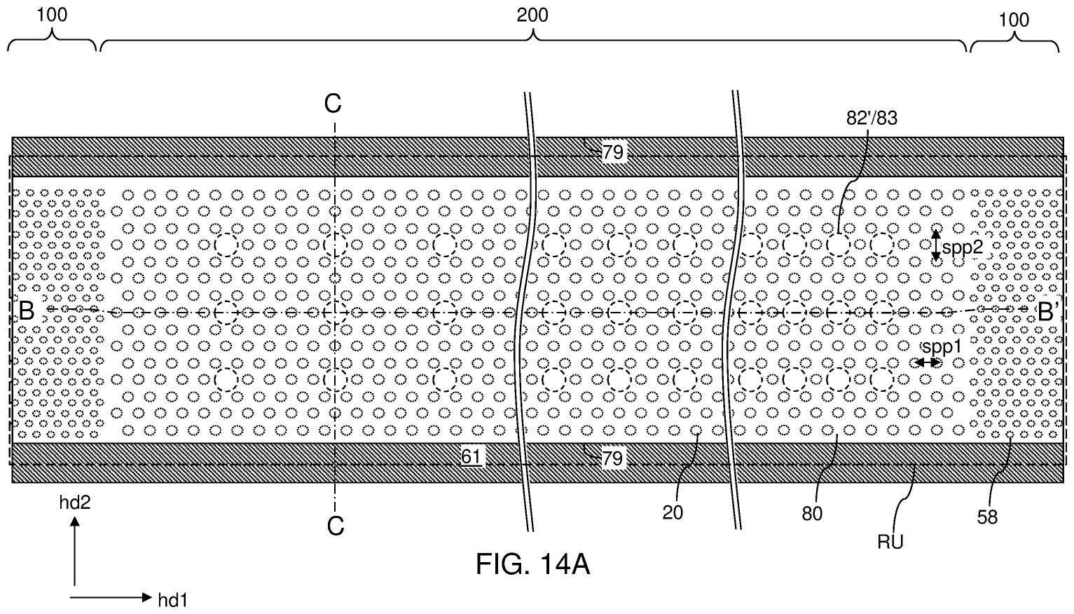

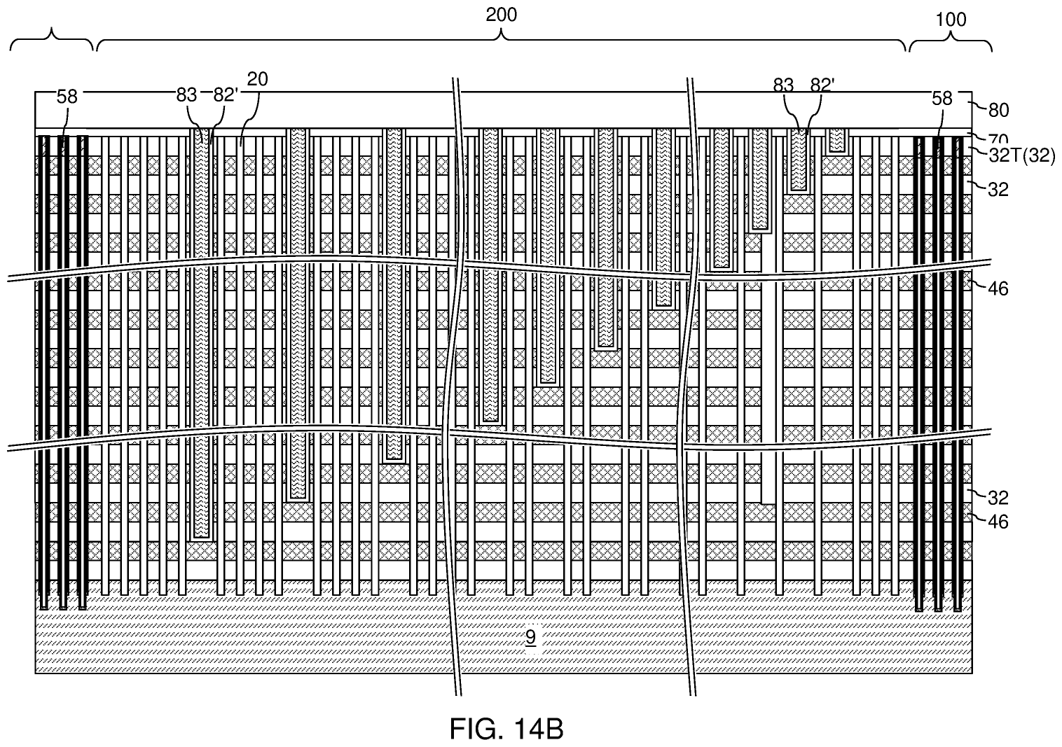

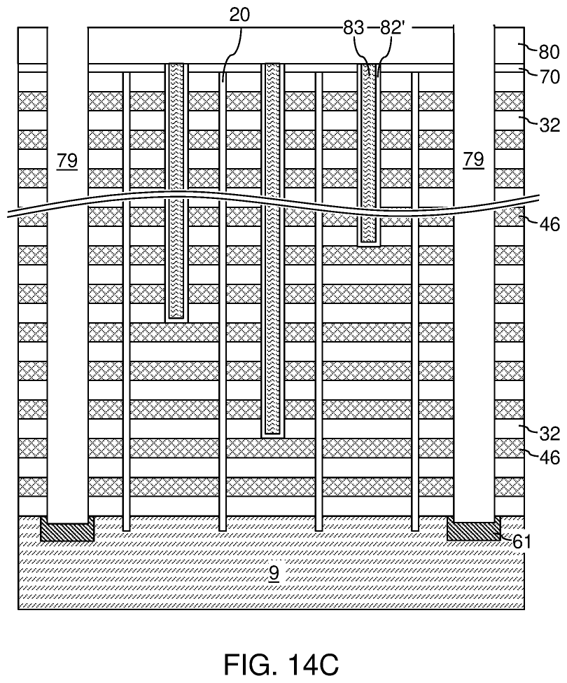

Referring to FIGS. 14A-14C, at least one conductive material, such as a combination of a metallic barrier liner material and a metal fill material, may be conformally deposited in the laterally-extending cavities 43, in peripheral regions of the lateral isolation trenches 79, and above the contact-level dielectric layer 80. The metallic barrier liner material may comprise a conductive metallic compound material such as TiN, TaN, WN, MON, TiC, TaC, WC, alloys thereof, or a combination thereof. The metal fill material may comprise W, Ti, Ta, Mo, Co, Ru, Cu, alloys thereof, or combinations thereof. The total thickness of the at least one conductive material is greater than one half of the height of each laterally-extending cavity 43.

A recess etch process can be performed to remove portions of the at least one conductive material that are present within the volumes of the lateral isolation trenches 79 or above the contact-level dielectric layer 80. The recess etch process may comprise an anisotropic etch process. Each remaining portion of the at least one conductive material filling a respective laterally-extending cavity 43 constitutes an electrically conductive layer 46. In one embodiment, sidewalls of the electrically conductive layers 46 in an alternating stack (32, 46) may be vertically coincident with (i.e., located within same vertical planes as) sidewalls of a pair of lateral isolation trenches 79.

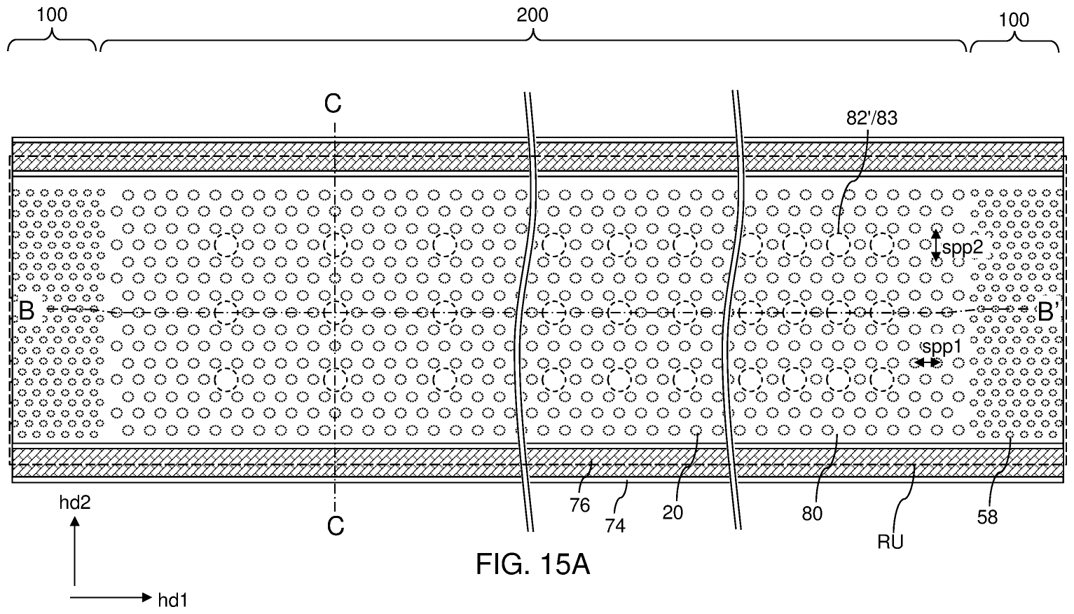

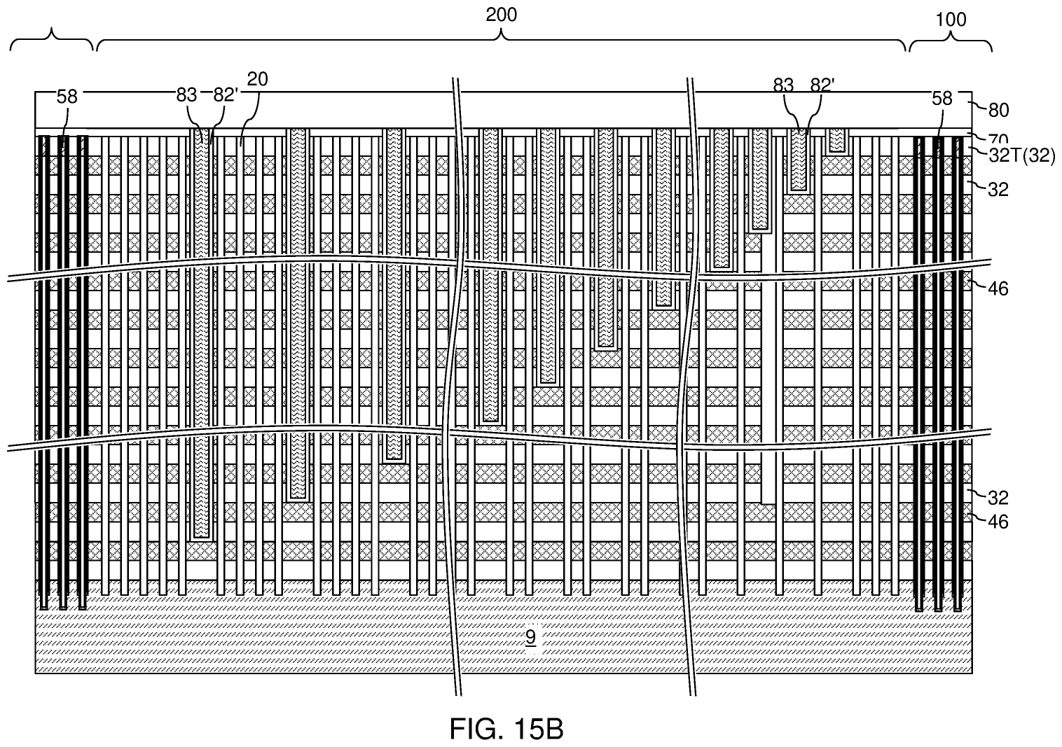

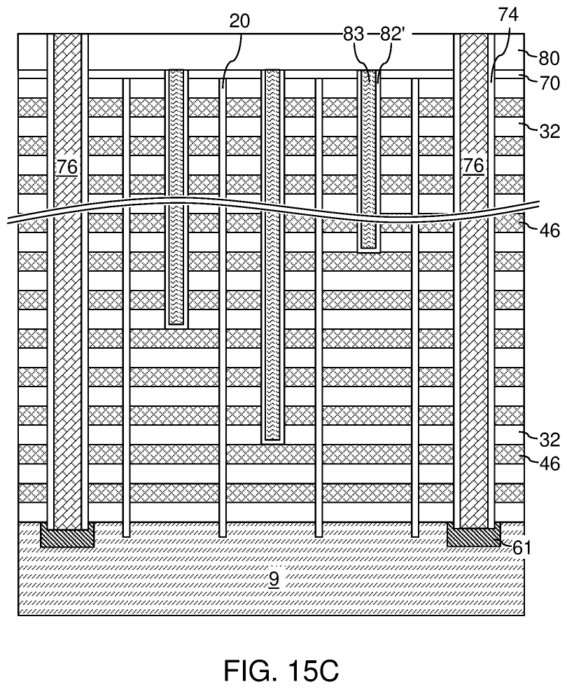

Referring to FIGS. 15A-15C, an insulating material layer can be formed in the lateral isolation trenches 79 and over the contact-level dielectric layer 80 by a conformal deposition process. An optional anisotropic etch can be performed to remove horizontal portions of the insulating material layer from above the contact-level dielectric layer 80 and at the bottom of each lateral isolation trench 79. Each remaining portion of the insulating material layer constitutes an insulating spacer 74. A lateral isolation cavity can be present within a volume surrounded by each insulating spacer 74. A top surface of the semiconductor material layer 9 can be physically exposed at the bottom of each lateral isolation trench 79.

An optional conductive trench fill structure 76 can be formed within each lateral isolation cavity. The conductive trench fill structures 76 can be formed by depositing at least one conductive material in the backside cavities. For example, the at least one conductive material can include a conductive liner and a conductive fill material portion. The conductive liner can include a conductive metallic liner such as TiN, TaN, WN, TIC, TaC, WC, an alloy thereof, or a stack thereof. The thickness of the conductive liner can be in a range from 3 nm to 30 nm, although lesser and greater thicknesses can also be employed. The conductive fill material portion can include a metal or a metallic alloy. For example, the conductive fill material portion can include W, Cu, Al, Co, Ru, Ni, an alloy thereof, or a stack thereof. Excess portions of the at least one conductive material can be removed from above the horizontal plane including the top surface of the contact-level dielectric layer 80 by a planarization process. The planarization process may comprise a recess etch process and/or a chemical mechanical polishing process. Each remaining portion of the at least one conductive material constitutes a conductive trench fill structure 76. A pair of lateral isolation trench fill structures (74, 76) can laterally contact each alternating stack (32, 46) of insulating layers 32 and electrically conductive layers 46. The pair of lateral isolation trench fill structures (74, 76) can be laterally spaced apart from each other by the alternating stack (32, 46). Each of pair of lateral isolation trench fill structures (74, 76) comprises a respective insulating sidewall that laterally extends along the first horizontal direction hd1 and contacting a respective set of sidewalls of the alternating stack (32, 46).

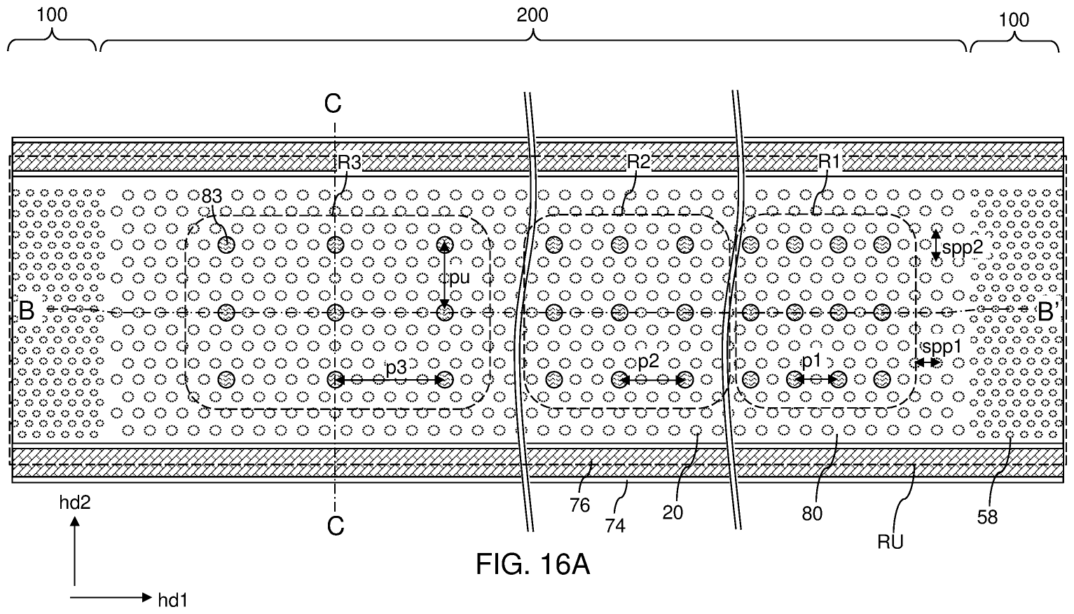

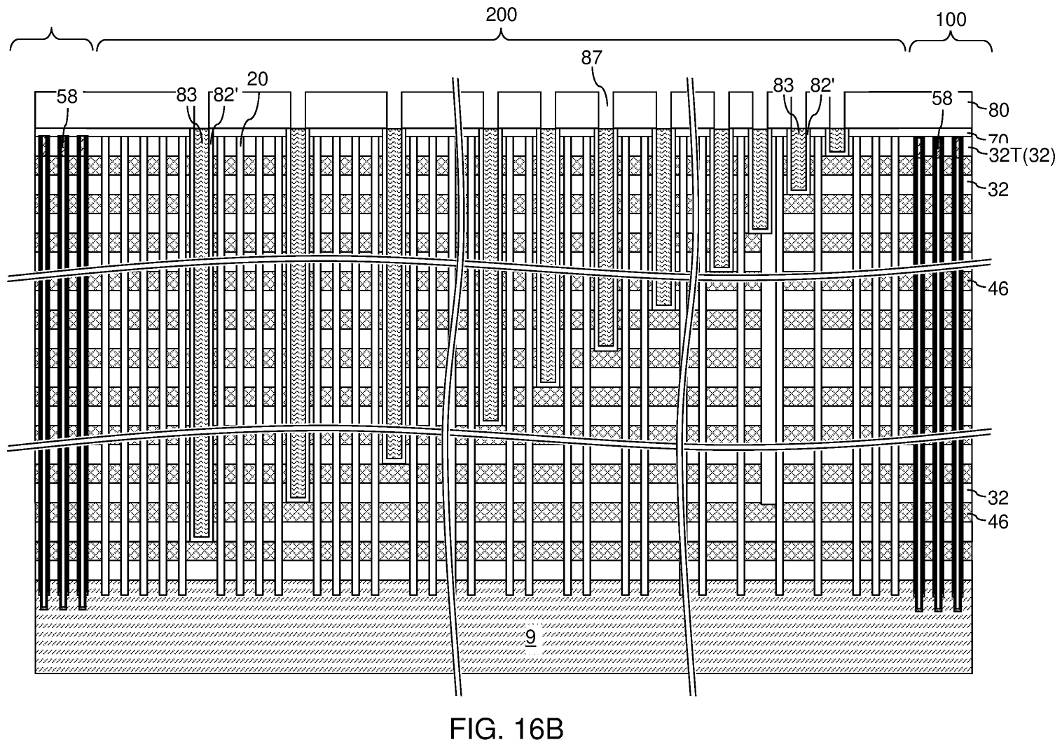

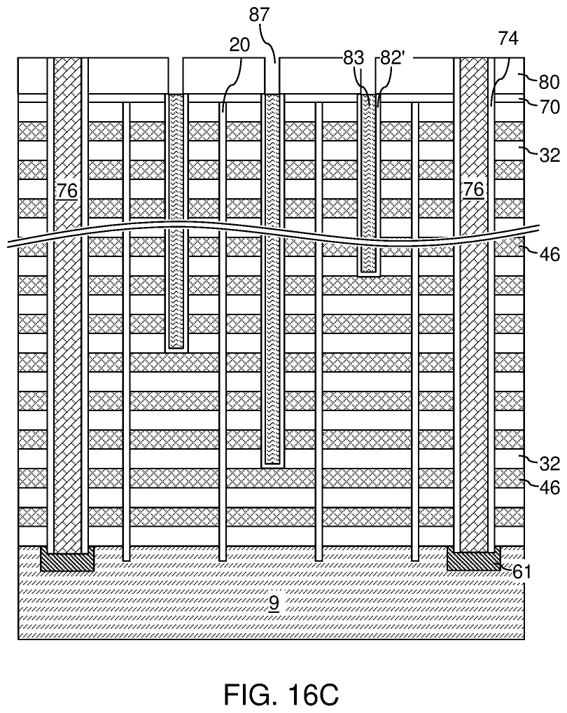

Referring to FIGS. 16A-16C, a photoresist layer (not shown) can be applied over the contact-level dielectric layer 80, and can be lithographically patterned to form openings within the areas of the sacrificial via opening fill structures 83 in a plan view. An anisotropic etch process can be performed to transfer the pattern of the openings in the photoresist layer through the contact-level dielectric layer 80. Connection via openings 87 can be formed through the contact-level dielectric layer 80. A top surface of a sacrificial via opening fill structure 83 can be physically exposed underneath each connection via opening 87. Additional openings can also be formed over the drain regions 63 of the memory opening fill structures 58. The photoresist layer can be subsequently removed, for example, by ashing.

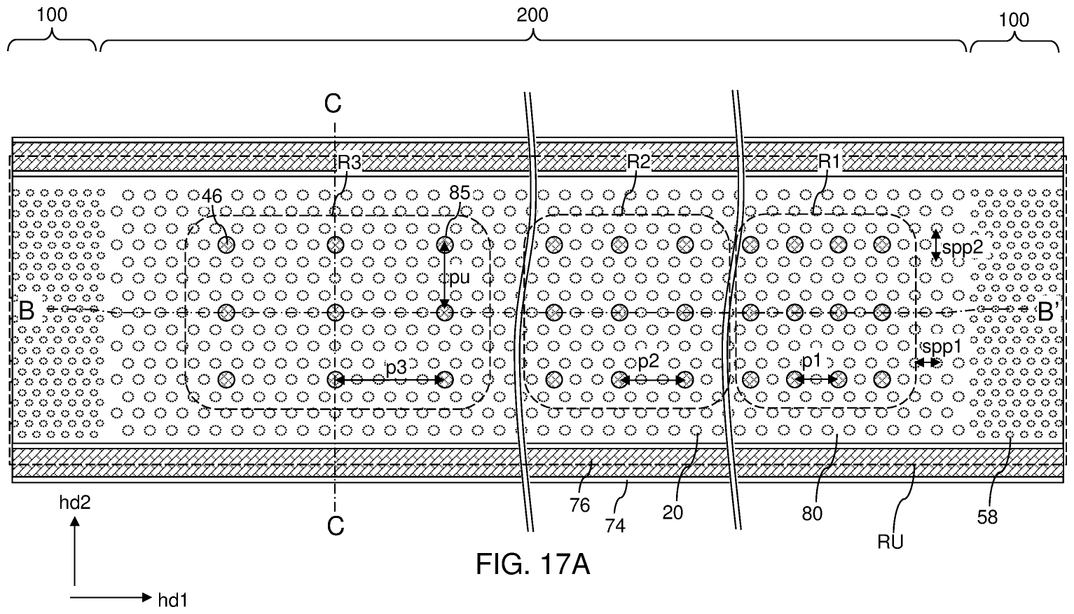

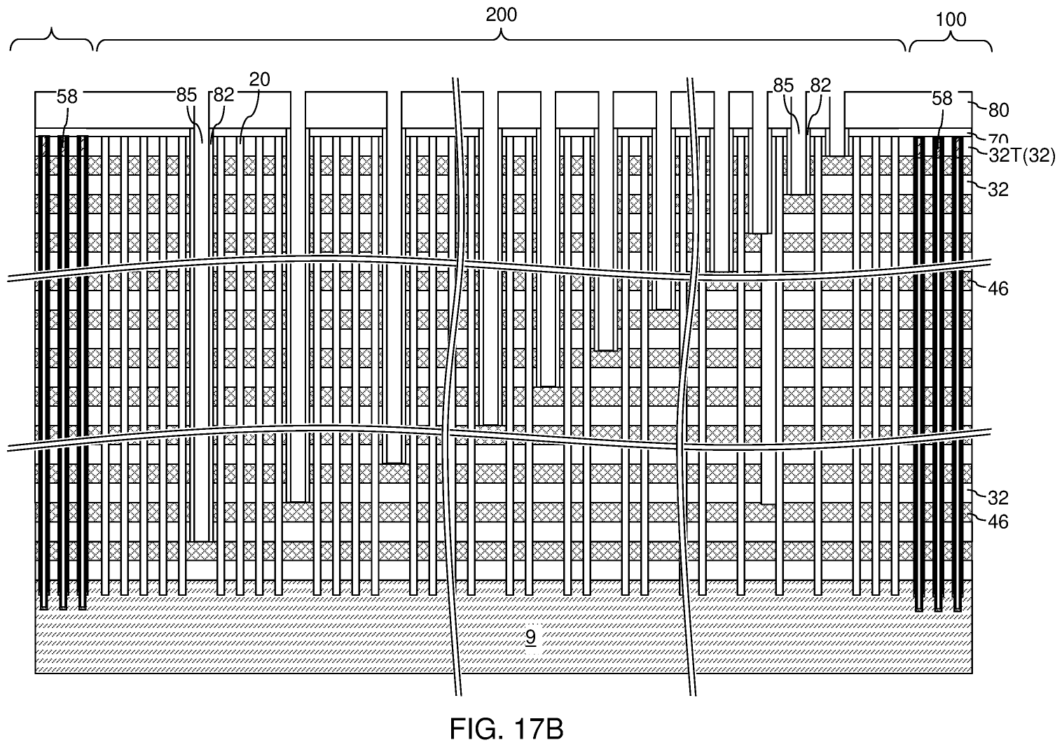

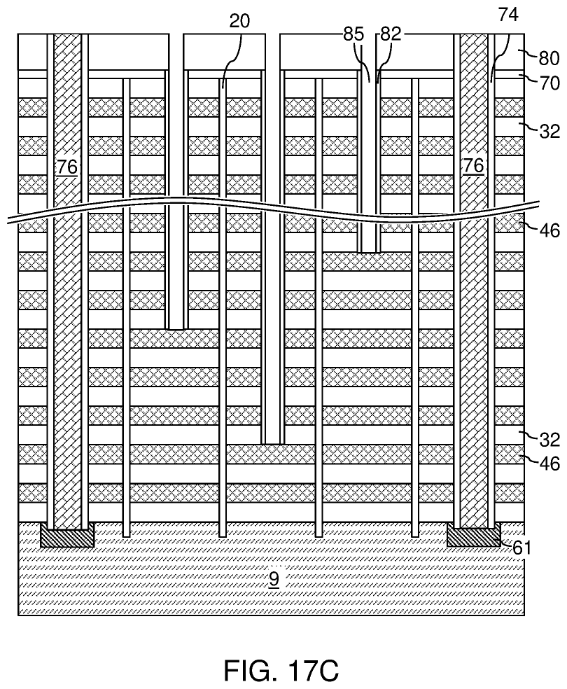

Referring to FIGS. 17A-17C, a selective removal process can be performed to remove the sacrificial via opening fill structures 83 selective to the materials of the insulating spacers 82′ and the contact-level dielectric layer 80. In one embodiment, the selective removal process may comprise a selective etch process or an ashing process. For example, if the sacrificial via opening fill structures 83 comprise a semiconductor material, a wet etch process that etches the semiconductor material selective to the dielectric materials of the insulating spacers 82′ and the contact-level dielectric layer 80 can be performed to remove the sacrificial via opening fill structures 83. Alternatively, if the sacrificial via opening fill structures 83 comprise a carbon-based material, an ashing process may be performed to remove the sacrificial via opening fill structures 83. Subsequently, an anisotropic etch process can be performed to remove bottom portions of the insulating spacers 82′.

The remaining portion of each insulating spacer 82′ has a tubular configuration, and is herein referred to as a tubular insulating spacer 82. Each volume of a void that is laterally surrounded by an insulating spacer 82′ constitutes a via cavity, which is herein referred to as a layer contact via cavity 85. A top surface segment of an electrically conductive layer 46 can be physically exposed underneath each layer contact via cavity 85.

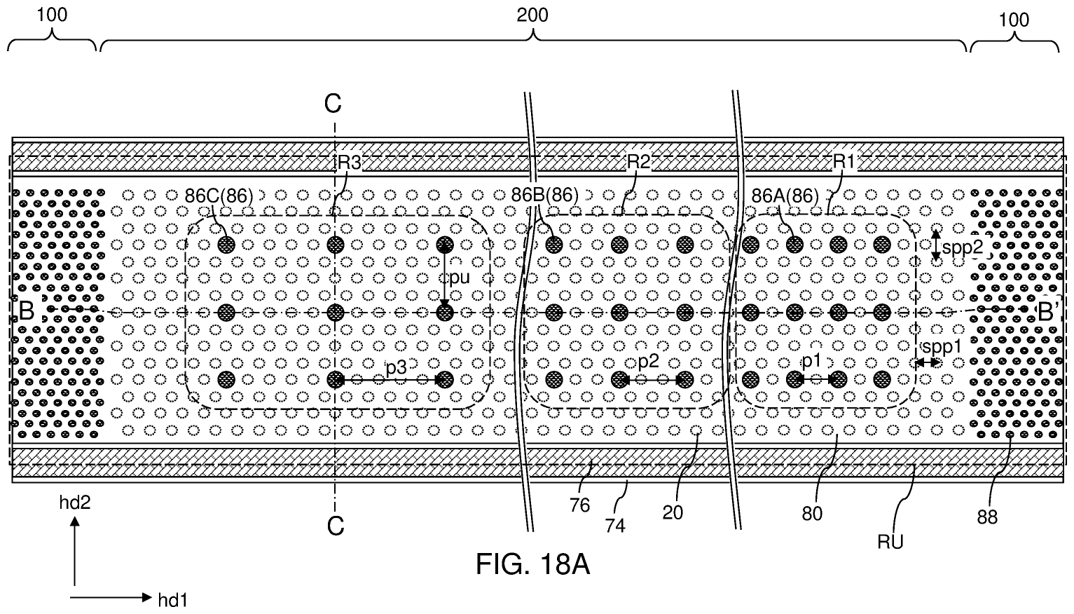

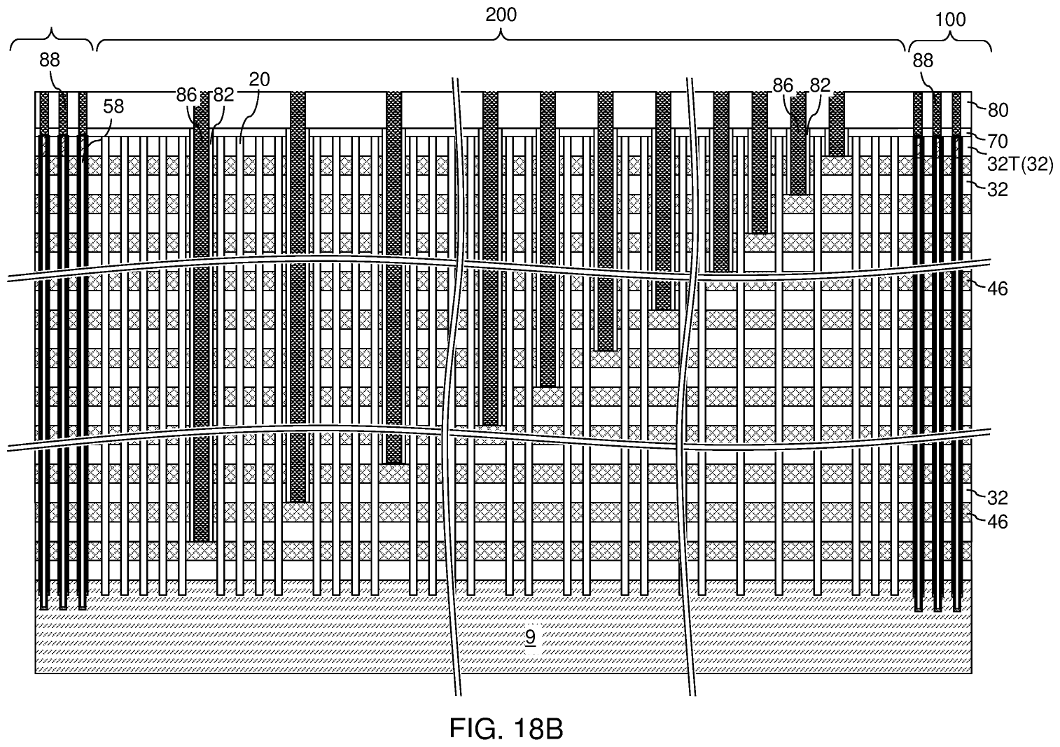

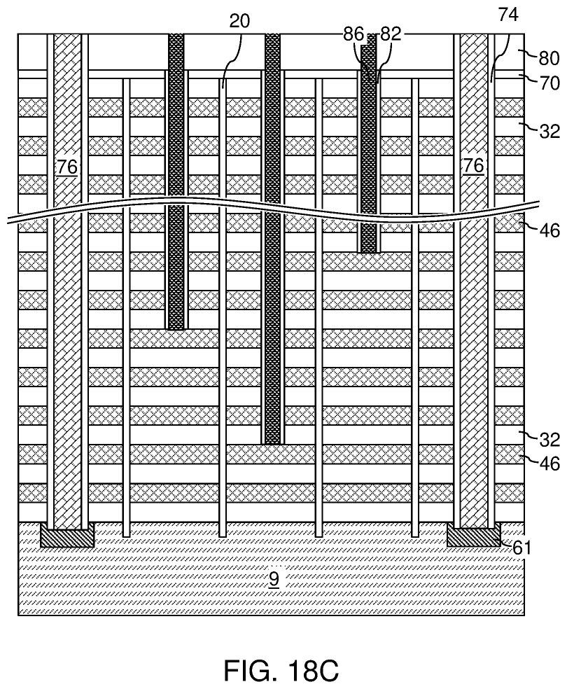

Referring to FIGS. 18A-18C, at least one conductive material can be deposited in the layer contact via cavities 85 and into openings that overly the drain regions 63. The at least one conductive material may comprise a combination of a metallic barrier material (such as TiN, TaN, WN, MON, etc.) and a metallic fill material (such as W, Cu, Mo, Ru, etc.). Excess portions of the at least one conductive material may be removed from above the horizontal plane including the top surface of the contact-level dielectric layer 80. Each layer contact via cavity 85 can be filled with a remaining portion of the at least one conductive material, which constitutes a layer contact via structure 86. The layer contact via structures 86 comprise first layer contact via structures 86A that are formed in the first region R1, second layer contact via structures 86B that are formed in the second region R2, and third layer contact via structures 86C that are formed in the third region R3. Drain contact via structures 88 are formed in contact with the drain regions 63. Subsequently, bit lines (not shown) are formed in electrical contact with the drain contact via structures 88.

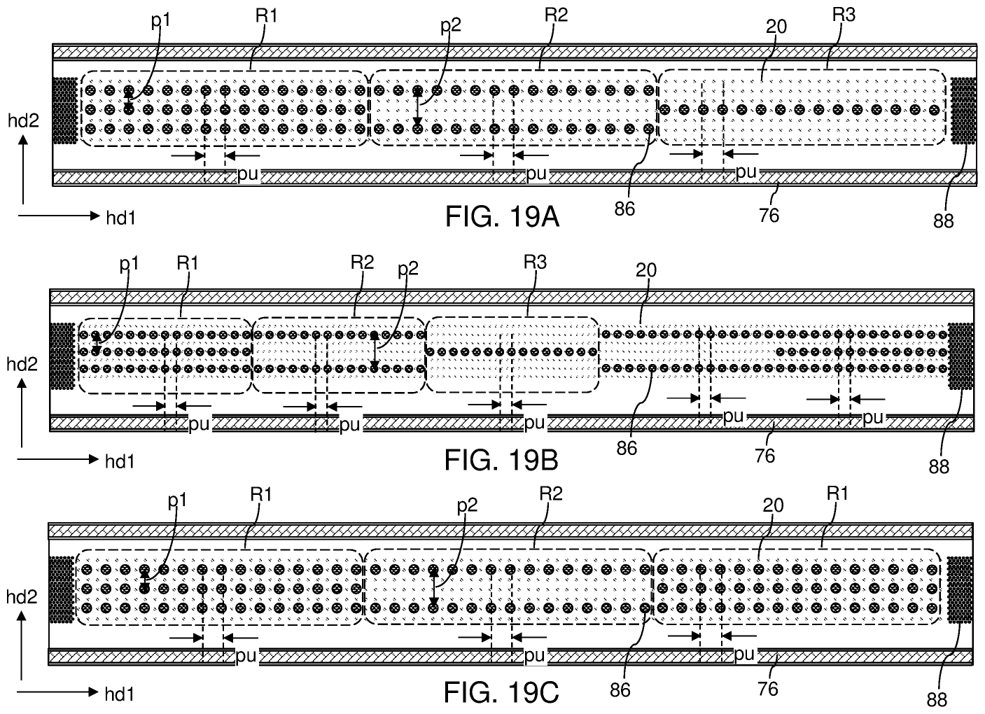

FIGS. 19A-19C are top-down views of alternative configuration of the exemplary structure after the processing steps of FIGS. 18A-18C according to the alternative embodiment of the present disclosure. The alternative configurations of the exemplary structure can be derived from the exemplary structure illustrated in FIGS. 18A-18C by employing the configurations described with reference to FIGS. 10A-10C in lieu of the configuration illustrated in FIGS. 18A-18C.

Referring collectively to FIGS. 18A-18C and 19A-19C, each of the layer contact via structures 86 is formed on a respective one of the electrically conductive layers 46 and vertically extends through a respective subset of layers within the alternating stack (32, 46) that overlies the respective one of the electrically conductive layers 46. In one embodiment, the three-dimensional memory device comprises: an alternating stack (32, 46) of insulating layers 32 and electrically conductive layers 46; memory openings 49 vertically extending through the alternating stack (32, 46); memory opening fill structures 58 located in the memory openings 49, wherein each of the memory opening fill structures 58 comprises a respective vertical stack of memory elements (e.g., portions of the memory film 50) and a vertical semiconductor channel 60; and an array of layer contact via structures 86. Each of the layer contact via structures 86 contacts a respective one of the electrically conductive layers 46 and vertically extends through a respective subset of layers within the alternating stack (32, 46) that overlies the respective one of the electrically conductive layers 46. A shallower first subset 86A of the layer contact via structures 86 has a higher density per unit area than a deeper second subset 86B of the layer contact via structures 86.

In one embodiment, the three-dimensional memory device contains a first region R1 including a first two-dimensional array of the first subset 86A of the layer contact via structures 86 that has a first average height and a first periodic pitch p1 along a first horizontal periodicity direction, and also contains a second region R2 including a second two-dimensional array of the second subset 86B of the layer contact via structures 86 having a second average height and a second periodic pitch p2 along the first horizontal periodicity direction. The three-dimensional memory device may also comprise a third region R3 including a third two-dimensional array of a third subset 86C of the layer contact via structures 86 having a third average height and a third periodic pitch p3 along the first horizontal periodicity direction. The second average height is greater than the first average height. The third average height is greater than the second average height. In one embodiment, the maximum height of the first subset 86A of the layer contact via structures 86 is less than the minimum height of the second subset 86B of the layer contact via structures 86. In one embodiment, the maximum height of the second subset 86B of the layer contact via structures 86 is less than the minimum height of the third subset 86C of the layer contact via structures 86. In one embodiment, the second periodic pitch p2 is greater than the first periodic pitch p1. In one embodiment, the third periodic pitch p3 is greater than the second periodic pitch p2.

In one embodiment, a ratio of the second average height to the first average height is in a range from 1.5 to 3; and a ratio of the second periodic pitch p2 to the first periodic pitch p1 is in a range from 1.2 to 2. In one embodiment, a ratio of the third average height to the second average height is in a range from 1.5 to 3; and a ratio of the third periodic pitch p3 to the second periodic pitch p2 is in a range from 1.2 to 2.

In one embodiment, the three-dimensional memory device comprises a pair of lateral isolation trench fill structures (74, 76) laterally extending along a first horizontal direction hd1, laterally spaced apart from each other along a second horizontal direction hd2 that is perpendicular to the first horizontal direction hd1, and comprising a respective insulating sidewall that laterally extends along the first horizontal direction hd1 and contacting a respective set of sidewalls of the alternating stack (32, 46), wherein one of the first horizontal direction hd1 and the second horizontal direction hd2 is the first horizontal periodicity direction. In one embodiment of FIGS. 18A-18C, the first horizontal periodicity direction is the first horizontal direction hd1. In another embodiment of FIGS. 19A-19C, the first horizontal periodicity direction is the second horizontal direction hd2.

In one embodiment, the first two-dimensional array comprises a first two-dimensional periodic array having a uniform pitch pu along a second horizontal periodicity direction that is different from the first horizontal periodicity direction; and the second two-dimensional array comprises a second two-dimensional periodic array having the uniform pitch pu along the second horizontal periodicity direction. In one embodiment, the three-dimensional memory device comprises a quasi-periodic two-dimensional array of support pillar structures 20 vertically extending through the alternating stack (32, 46). The support pillar structures 20 in the quasi-periodic two-dimensional array are located at a primary subset of lattice sites of a first periodic two-dimensional array having a first support-pillar periodicity spp1 along a first horizontal direction hd1 and having a second support-pillar periodicity spp2 along a second horizontal direction hd2 in a plan view; and the layer contact via structures 86 are located at a complementary subset of the vacancy lattice sites of the first periodic two-dimensional array.

In one embodiment, the second region R2 is laterally spaced from the first region R1 along the first horizontal direction hd1. In one embodiment, the first horizontal direction hd1 is parallel to the first horizontal periodicity direction; and the second horizontal direction hd2 is perpendicular to the first horizontal periodicity direction. In one embodiment, the first periodic pitch p1 is a first integer multiple of the first support-pillar periodicity spp1; and the second periodic pitch p2 is a second integer multiple of the first support-pillar periodicity spp1. In one embodiment, the first periodic pitch p1 is a first integer multiple of the second support-pillar periodicity spp2; and the second periodic pitch p2 is a second integer multiple of the second support-pillar periodicity spp2 different from the first integer multiple.

In one embodiment, the first subset of the layer contact via structures 86 is located at lattice sites of a first subset of the complementary subset in the first region R1; and the second subset of the layer contact via structures 86 is located at lattice sites of a second subset of the complementary subset in the second region R2. In one embodiment, the first subset of the complementary subset has a uniform pitch pu along a second horizontal periodicity direction that is different from the first horizontal periodicity direction; and the second subset of the complementary subset has the uniform pitch pu along the second horizontal periodicity direction. In one embodiment, each of the layer contact via structures 86 is laterally surrounded by a respective tubular insulating spacer 82 that vertically extends between the respective one of the electrically conductive layers 46 to a horizontal plane located at or above a topmost surface of the alternating stack (32, 46).

Although the foregoing refers to particular preferred embodiments, it will be understood that the claims are not so limited. It will occur to those of ordinary skill in the art that various modifications may be made to the disclosed embodiments and that such modifications are intended to be within the scope of the claims. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the claims may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

1. A three-dimensional memory device, comprising:
an alternating stack of insulating layers and electrically conductive layers;
memory openings vertically extending through the alternating stack;
memory opening fill structures located in the memory openings, wherein each of the memory opening fill structures comprises a respective vertical semiconductor channel and a vertical stack of memory elements; and
an array of layer contact via structures,
wherein:
each of the layer contact via structures contacts a respective one of the electrically conductive layers and vertically extends through a respective subset of layers within the alternating stack that overlies the respective one of the electrically conductive layers; and
a shallower first subset of the layer contact via structures has a higher density per unit area than a deeper second subset of the layer contact via structures.

2. The three-dimensional memory device of claim 1, wherein:
a first region comprises a first two-dimensional array of the first subset of the layer contact via structures has a first average height and a first periodic pitch along a first horizontal periodicity direction;
a second region comprises a second two-dimensional array of the second subset of the layer contact via structures having a second average height and a second periodic pitch along the first horizontal periodicity direction;
the second average height is greater than the first average height; and
the second periodic pitch is greater than the first periodic pitch.

3. The three-dimensional memory device of claim 2, wherein:
a ratio of the second average height to the first average height is in a range from 1.5 to 3; and
a ratio of the second periodic pitch to the first periodic pitch is in a range from 1.2 to 2.

4. The three-dimensional memory device of claim 2, further comprising a pair of lateral isolation trench fill structures laterally extending along a first horizontal direction, laterally spaced apart from each other along a second horizontal direction that is perpendicular to the first horizontal direction, and comprising a respective insulating sidewall that laterally extends along the first horizontal direction and contacting a respective set of sidewalls of the alternating stack, wherein one of the first horizontal direction and the second horizontal direction is the first horizontal periodicity direction.

5. The three-dimensional memory device of claim 4, wherein the first horizontal periodicity direction is the first horizontal direction.

6. The three-dimensional memory device of claim 4, wherein the first horizontal periodicity direction is the second horizontal direction.

7. The three-dimensional memory device of claim 2, wherein:
the first two-dimensional array comprises a first two-dimensional periodic array having a uniform pitch along a second horizontal periodicity direction that is different from the first horizontal periodicity direction; and
the second two-dimensional array comprises a second two-dimensional periodic array having the uniform pitch along the second horizontal periodicity direction.

8. The three-dimensional memory device of claim 2, further comprising a quasi-periodic two-dimensional array of support pillar structures vertically extending through the alternating stack, wherein:
the support pillar structures in the quasi-periodic two-dimensional array are located at a primary subset of lattice sites of a first periodic two-dimensional array having a first support-pillar periodicity along a first horizontal direction and having a second support-pillar periodicity along a second horizontal direction in a plan view;
the layer contact via structures are located at a complementary subset of the lattice sites of the first periodic two-dimensional array; and
the second region is laterally spaced from the first region along the first horizontal direction.

9. The three-dimensional memory device of claim 8, wherein:
the first horizontal direction is parallel to the first horizontal periodicity direction; and
the second horizontal direction is perpendicular to the first horizontal periodicity direction.

10. The three-dimensional memory device of claim 8, wherein:
the first periodic pitch is a first integer multiple of the first support-pillar periodicity; and
the second periodic pitch is a second integer multiple of the first support-pillar periodicity which is different from the first integer multiple.

11. The three-dimensional memory device of claim 8, wherein:
the first periodic pitch is a first integer multiple of the second support-pillar periodicity; and
the second periodic pitch is a second integer multiple of the second support-pillar periodicity which is different from the first integer multiple.

12. The three-dimensional memory device of claim 8, wherein:
the first subset of the layer contact via structures is located at lattice sites of a first subset of the complementary subset in the first region; and
the second subset of the layer contact via structures is located at lattice sites of a second subset of the complementary subset in the second region.

13. The three-dimensional memory device of claim 8, wherein
the first subset of the complementary subset has a uniform pitch along a second horizontal periodicity direction that is different from the first horizontal periodicity direction; and
the second subset of the complementary subset has the uniform pitch along the second horizontal periodicity direction.

14. The three-dimensional memory device of claim 1, wherein each of the layer contact via structures is laterally surrounded by a respective tubular insulating spacer that vertically extends between the respective one of the electrically conductive layers to a horizontal plane located at or above a topmost surface of the alternating stack.

15. A method of forming a three-dimensional memory device, comprising:
forming an alternating stack of insulating layers and spacer material layers, wherein the spacer material layers are formed are or are subsequently replaced with electrically conductive layers;
forming memory openings through the alternating stack;
forming memory opening fill structures in the memory openings, wherein each of the memory opening fill structures comprises a respective vertical semiconductor channel and a vertical stack of memory elements; and
forming an array of layer contact via structures,
wherein:
each of the layer contact via structures is formed on a respective one of the electrically conductive layers and vertically extends through a respective subset of layers within the alternating stack that overlies the respective one of the electrically conductive layers; and
a shallower first subset of the layer contact via structures has a higher density per unit area than a deeper second subset of the layer contact via structures.

16. The method of claim 15, wherein:
a first region comprises a first two-dimensional array of the first subset of the layer contact via structures that has a first average height and a first periodic pitch along a first horizontal periodicity direction; and
a second region comprises a second two-dimensional array of the second subset of the layer contact via structures having a second average height and a second periodic pitch along the first horizontal periodicity direction;
the second average height is greater than the first average height; and
the second periodic pitch is greater than the first periodic pitch.

17. The method of claim 16, further comprising:
forming a pair of lateral isolation trenches laterally extending along a first horizontal direction through the alternating stack, wherein the pair of lateral isolation trenches is laterally spaced apart from each other along a second horizontal direction that is perpendicular to the first horizontal direction; and
forming a pair of lateral isolation trench fill structures in the pair of lateral isolation trenches, wherein each of the pair of lateral isolation trench fill structures comprises a respective insulating sidewall that laterally extends along the first horizontal direction and contacting a respective set of sidewalls of the alternating stack, and wherein one of the first horizontal direction and the second horizontal direction is the first horizontal periodicity direction.

18. The method of claim 16, further comprising forming a quasi-periodic two-dimensional array of support pillar structures vertically extending through the alternating stack, wherein:
the support pillar structures in the quasi-periodic two-dimensional array are located at a primary subset of lattice sites of a first periodic two-dimensional array having a first support-pillar periodicity along a first horizontal direction and having a second support-pillar periodicity along a second horizontal direction in a plan view; and
the layer contact via structures are located at a complementary subset of the lattice sites of the first periodic two-dimensional array.

19. The method of claim 18, wherein:
the second region is laterally spaced from the first region along the first horizontal direction;
the first horizontal direction is parallel to the first horizontal periodicity direction; and
the second horizontal direction is perpendicular to the first horizontal periodicity direction.

20. The method of claim 18, wherein:
the first subset of the layer contact via structures is formed at lattice sites of a first subset of the complementary subset in the first region; and
the second subset of the layer contact via structures is formed at lattice sites of a second subset of the complementary subset in the second region.
